(19) United States
(12) Patent Application Publication
(10) Pub. No.: US 2026/0304950 A1
(43) Pub. Date: Oct. 1, 2026

(54) GATE TUB WALL ARCHITECTURE SELF-ALIGNED TO FINS

(71) Applicant: Intel Corporation, Santa Clara, CA (US)

(72) Inventors: Dan Lavric, Portland, OR (US); Leonard Guler, Hillsboro, OR (US); Glenn Glass, Portland, OR (US)

(73) Assignee: Intel Corporation, Santa Clara, CA (US)

(21) Appl. No.: 19/092,845

(22) Filed: Mar. 27, 2025

(51) Int. Cl. H10D 84/85; H10D 30/00; H10D 30/01; H10D 30/47; H10D 62/10; H10D 62/13; H10D 84/01

(52) U.S. Cl. CPC H10D 84/856; H10D 30/017; H10D 30/019; H10D 30/47; H10D 30/502; H10D 62/102; H10D 62/121; H10D 62/151; H10D 84/0181; H10D 84/0188; H10D 84/851

(57) ABSTRACT

Integrated circuit (IC) devices having gate-all-around (GAA) transistors. An IC device may include a vertical dielectric wall centered between first and second nanoribbon stacks through first and second gate structures of first and second transistor structures, and the first and second gate structures may have corresponding first and second gate dielectric layers on the respective first and second nanoribbons and on opposing first and second sidewalls of the vertical dielectric wall. The vertical dielectric wall may have virtually no taper and may be exactly between the first and second nanoribbon stacks. The vertical dielectric wall may be between the first and second gate structures, but not between corresponding source and drain epi bodies. The vertical dielectric wall may be self-aligned between stacks of nanoribbons, formed by conformally depositing a dielectric layer between conformally deposited spacer layers between stacks of channel material layers.

### BACKGROUND

In conventional processing of gate-all-around (GAA) transistors, the gate electrodes and gate insulators of millions of transistors are fabricated concurrently and with matching characteristics (such as gate dielectric thickness). Even minimal modifications in gate processing for complementary transistors (e.g., differences between n- and p-type transistor fabrication) may cause surface defects and excessive consumption of channel material. For example, repeated deposition and removal of masking layers may consume channel materials and/or damage channel materials or gate dielectrics. Furthermore, typical methods (for example, lithographic masking) are increasingly challenged by the tightening dimensions of contemporary GAA transistors. Previously satisfactory tolerances (e.g., for mask registration errors, etc.) are proving inadequate, and proposed advances (such as more intricate lithography) are not without problems and may be excessively expensive.

New techniques, structures, and materials are needed to improve the performance and reliability of integrated circuit (IC) devices, for example, by providing multiple transistor gate variants whose characteristics (such as leakage or switching speed) may be matched to particular applications. The new techniques, structures, and materials are particularly necessary given the shrinking area constraints of modern GAA transistors.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, and 1D illustrate cross-sectional profile and plan views of an integrated circuit (IC) device having with a narrow dielectric wall centered between stacks of nanoribbons having different gate stacks in transistor structures, in accordance with some embodiments;

FIG. 2 is a flow chart of methods for forming vertical, self-aligned dielectric walls for gate tub isolation, in accordance with some embodiments;

FIGS. 3A, 3B, 3C, 3D, 3E, 3F, 3G, 3H, 3I, 3J, 3K and 3L illustrate cross-sectional profile views of an IC device having vertical, self-aligned dielectric walls between gate structures, at various stages of manufacture, in accordance with some embodiments;

FIG. 4 illustrates a diagram of an example data server machine employing an IC device having vertical dielectric walls that extend between gate electrodes but not to between source and drain bodies, in accordance with some embodiments; and

FIG. 5 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures, techniques, and materials are disclosed to improve integrated circuit (IC) devices having gate-all-around (GAA) metal-oxide-semiconductor (MOS) field-effect transistors (FETs).

Dielectric walls may separate adjacent nanoribbon stacks into individual gate processing compartments (“tubs”), thereby enabling independent fabrication of gate dielectric stacks in adjacent GAA FETs. Instead of every nanoribbon stack in a shared gate trench undergoing the same processing, each nanoribbon stack may have its own gate tub and receive specifically tailored processing. The dielectric walls may be self-aligned walls, centered between adjacent nanoribbon stacks. The dielectric walls may be formed exactly midway between adjacent material layer fins or stacks, e.g., nanoribbon stacks before the nanoribbons are cut into individual stacks or the nanoribbons are released, by depositing conformal spacer layers over the material layer fins or stacks. The conformal spacer layers may be deposited by a precisely controlled method (such as an atomic layer deposition (ALD) to ensure that the conformal spacer layers are deposited evenly on both sides of every material layer fin or stack and exactly to the desired thickness. The dielectric walls may be formed in the precisely controlled gaps between conformal spacer layers on adjacent material layer fins or stacks. This self-aligned method enables the fabrication of dielectric walls approaching perfect verticality and to any particular thickness.

Openings may be patterned through a hardmask layer deposited over the dielectric walls and nanoribbon stacks, and dummy-gate material may be removed through the openings, evacuating selected tubs between the dielectric walls. The mask openings may be made to evacuate groups of tubs selected for a particular processing operation. For example, the gate tubs for all (or at least many) nanoribbon stacks to receive a certain gate dielectric material or thickness may be evacuated together and then receive the further processing concurrently. The hardmask layer may be removed following the completion of the particular processing operation, a new hardmask layer may be deposited, and new openings may be patterned to evacuate a new group of tubs for a next processing operation (e.g., the formation of a second gate dielectric material or thickness). The dielectric walls may be retained after gate formation as electrical isolation between adjacent metal gate electrodes.

The tailored processing enabled by the gate tubs may be used to provide multiple gate variants, for example, having different threshold voltages V_{T} and corresponding leakages and switching speeds. An IC device may have multiple gate variants for each of multiple complementary conductivity types. For example, an IC device may have a spread of four or more threshold voltages V_{T} among NMOS FETs and a spread of four or more threshold voltages V_{T} among PMOS FETs. In many embodiments, adjacent transistors have different thicknesses of gate dielectric layers directly on channel nanoribbons. In many embodiments, adjacent transistors have different thicknesses of gate dielectric layers (e.g., high-permittivity or “high-k” layers) over the layers directly on the nanoribbons. For example, gate dielectric layer thicknesses may differ by 2 angstroms (or as much as 5 angstroms) in adjacent transistors. In many embodiments, adjacent transistors have gate dielectric layers with different high-k materials. In some embodiments, adjacent transistors have gate dielectric layers with different material compositions (e.g., elemental ratios) of the same high-k materials.

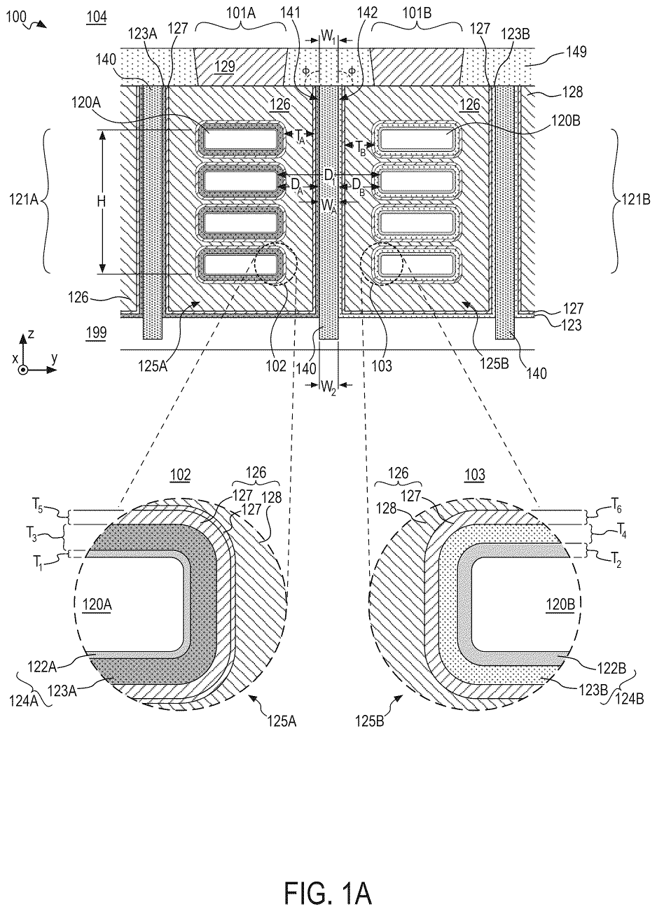

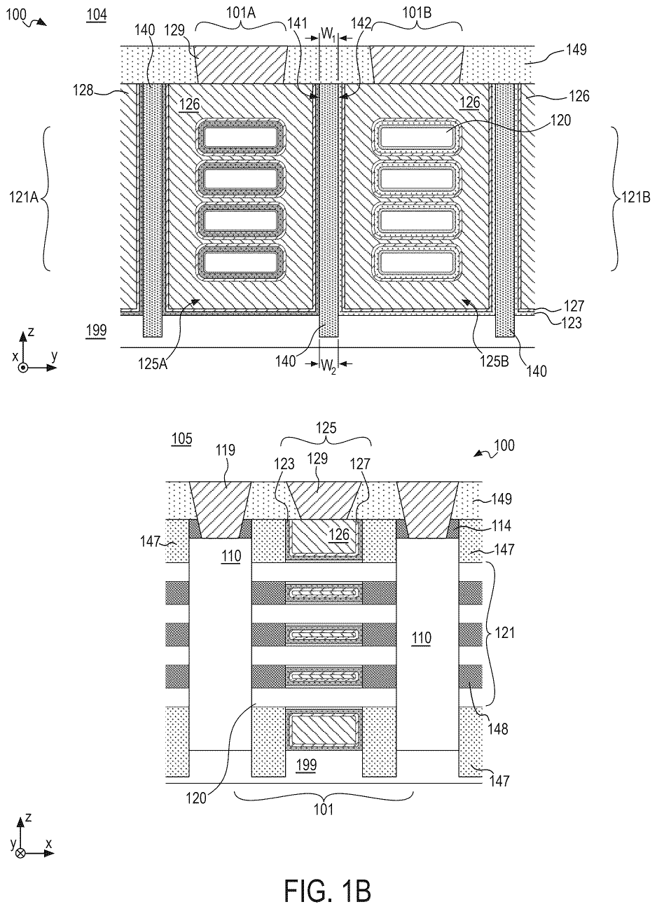

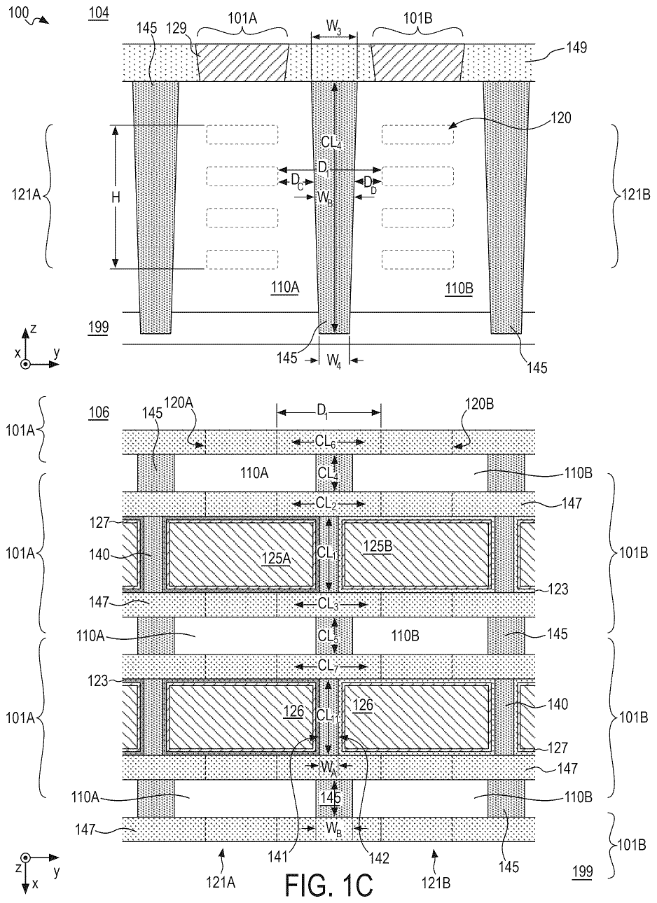

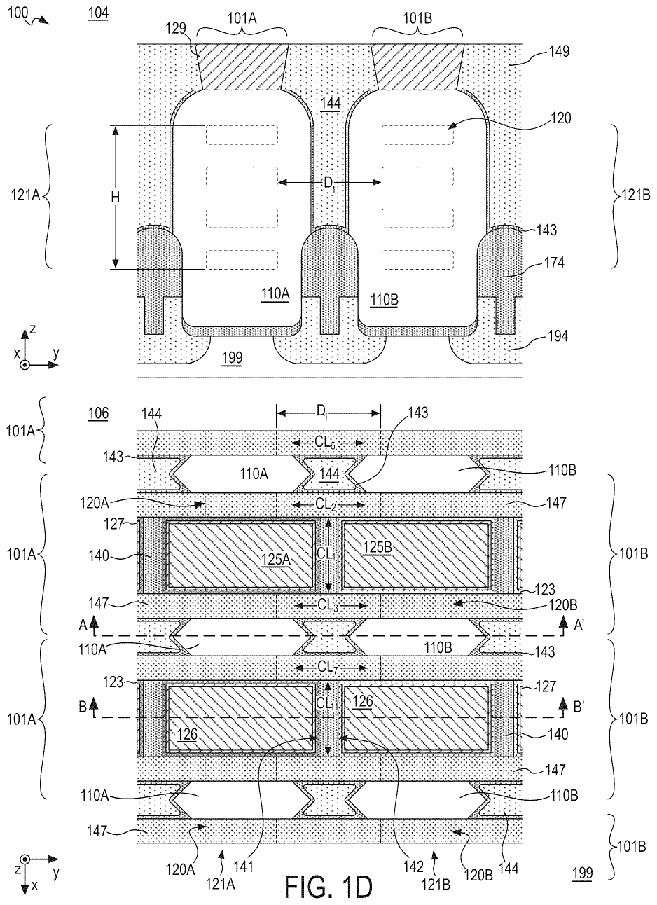

FIGS. 1A, 1B, 1C, and 1D illustrate cross-sectional profile and plan views of an IC device 100 with a narrow dielectric wall 140 centered between stacks 121A, 121B of nanoribbons 120A, 120B having different gate stacks 125A, 125B in transistor structures 101A, 101B, in accordance with some embodiments. Transistor structures 101A, 101B are GAA FET structures 101 having channel regions in stacks 121A, 121B of nanoribbons 120 (e.g., nanoribbons 120A, 120B). FIG. 1A shows a main view 104 with a y-z viewing plane transversely through nanoribbons 120 in multiple, adjacent stacks 121A, 121B and transistor structures 101. FIG. 1A also includes enlarged views 102, 103 of gate stacks 125A, 125B on nanoribbons 120A, 120B. FIG. 1B illustrates a view 105 with an x-z viewing plane longitudinally through nanoribbons 120 in transistor structure 101, as well as y-z view 104, e.g., for reference. FIG. 1C shows a plan view 106 of transistor structures 101A, 101B, with an x-y viewing plane through dielectric walls 140 between gate stacks 125A, 125B and between spacers 147, as well as y-z view 104, e.g., for reference. FIG. 1D illustrates a similar x-y plan view 106 of transistor structures 101A, 101B, but of embodiments having different isolation between source or drain bodies 110, as well as y-z view 104, e.g., for reference.

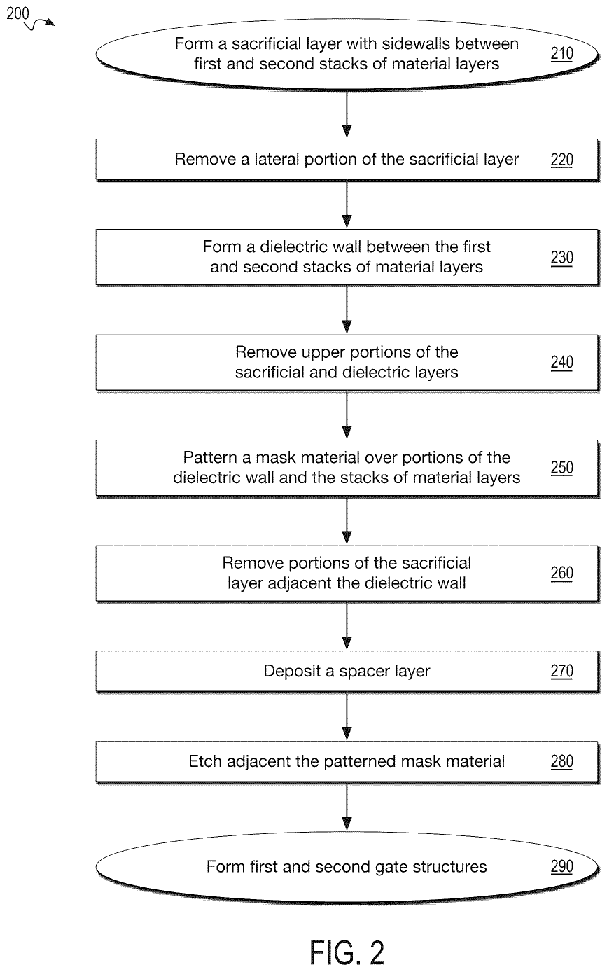

FIG. 1A shows device 100 including isolation wall 140 between and separating first and second gate stacks 125A, 125B in transistor structures 101A, 101B, respectively, in accordance with some embodiments. Isolation wall 140 is a dielectric structure on (e.g., in contact with) both of stacks 125A, 125B. Wall 140, separating gate stacks 125A, 125B and electrodes 126, extends vertically from above the tops (e.g., upper surfaces) of electrodes 126 to below the bottoms (e.g., lower surfaces) of electrodes 126. Dielectric wall 140 provides isolation (e.g., electrical isolation) between gate electrodes 126 of structures 101A, 101B. A thin, vertical wall 140 enables the tight packing of transistor structures 101A, 101B and gate electrodes 126 in device 100, even for very tall stacks 121 of nanoribbons 120, for example, with higher quantities of nanoribbons 120. Dielectric wall 140 also enables the independent processing of gate stacks 125A, 125B in structures 101A, 101B (e.g., as described elsewhere herein, such as at FIG. 2 and methods 200), which allows for stacks 125 having different insulator layers 122, 123, etc., for example, with different thicknesses, materials, etc. Each wall 140 is between a pair of gate electrodes 126, and each electrode 126 is between a pair of dielectric walls 140.

Wall 140 includes opposing first and second sidewalls 141, 142. A width W₁ (or width W₂) of dielectric wall 140 separates sidewalls 141, 142. Width W₁ (or width W₂) separates first and second gate stacks 125A, 125B on gate electrodes 126 in transistor structures 101A, 101B (respectively). Dielectric wall 140 (e.g., sidewalls 141, 142) are vertical. For example, each of sidewalls 141, 142 are both less than half of one degree from vertical. Angle φ between each of sidewalls 141, 142 (extended into layer 149) are both equal to 90°±0.5°. In many embodiments, widths W₁, W₂ of wall 140 are approximately equal (e.g., within 1 nm, with virtually no tapering upwards or downwards). For example, in many embodiments, widths W₁, W₂ differ by 0.5 nm or less. Width W₁ is defined as the width of wall 140 at a top of wall 140, above the stacks of nanoribbons 120A, 120B. Width W₂ is defined as the width of wall 140 at a bottom of stacks 125, e.g., where wall 140 meets substrate 199 at a bottom of stacks 125, below the stacks of nanoribbons 120A, 120B. Wall 140 includes a width W_{A} at a height between the heights of widths W₁, W₂ (for example, at a midpoint of height H) separating sidewalls 141, 142. In many embodiments, width W_{A} of dielectric wall 140 is equal to widths W₁, W₂.

Gate stacks 125 (e.g., gate structures that include electrodes 126) are separated by dielectric wall 140 and a minimum distance or width W₂ (or width W₁, etc.) between stacks 125. In many embodiments, dielectric wall 140 has a minimum width W₂ (or width W₁, etc.) of 10 nm or less between stacks 125, which may enable sufficiently tight packing of transistor structures 101A, 101B and a consequent conservation of layout area. In some embodiments, dielectric wall 140 has a minimum width W₂ (or width W₁, etc.) of approximately 9 nm between electrodes 126 (and stacks 125), which may enable superior packing of transistor structures 101A, 101B and conservation of layout area. Such (small widths W₁, W₂ and) tight laying out of structures 101 may be enabled by a vertical, self-aligned dielectric wall 140 centered precisely between stacks 121A, 121B of nanoribbons 120A, 120B, e.g., enabled by using low-variation methods 200 (described elsewhere herein, such as at FIG. 2).

The tight packing of stacks 121 and transistor structures 101 may also be characterized by a small distance D₁ separating the first and second stacks 121A, 121B of nanoribbons 120A, 120B, for example, relative to height H. In many embodiments, distance D₁ separating stacks 121A, 121B of nanoribbons 120A, 120B is less than half of height H of stack 121A or 121B of nanoribbons 120. The small distance D₁ (and/or tall height H) may be enabled by a thin and well-controlled (e.g., repeatably manufactured) dielectric wall 140 centered between stacks 121A, 121B, which may be difficult (e.g., infeasible) to achieve with a conventional etch. The repeatable manufacturing of dielectric wall 140 may be by the novel methods 200 described (at least) at FIG. 2.

A small distance D₁ may also be characterized relative to either of widths W₁, W₂. In many embodiments, distance D₁ is less than three times a maximum width W₁ (or width W₂) of wall 140 (e.g., with wall 140 exactly centered between stacks 121, less than a width W₁ from either stack). In other embodiments, although distance D₁ may be small, a very narrow wall 140 has a maximum width W₁ (or width W₂) less than a third of even a very small distance D₁. In some embodiments, each of first and second thicknesses T_{A}, T_{B} are greater than width W₁ (or width W₂) of dielectric wall 140. Thicknesses T_{A}, T_{B} are of gate electrodes 126, e.g., of gate metal, in gate stacks 125A, 125B (and transistor structures 101A, 101B), respectively. Thickness T_{A} is of electrode 126 between wall 140 and nanoribbons 120A (separated from each of wall 140 and nanoribbons 120A by at least dielectric layer 123A). Thickness T_{B} is of electrode 126 between wall 140 and nanoribbons 120B (separated from each of wall 140 and nanoribbons 120B by at least dielectric layer 123B). In other embodiments, a well-controlled dielectric wall 140 (e.g., repeatably manufactured with minimal variation) enables thin or narrow thicknesses T_{A}, T_{B}, both less or shorter than width W₁ (or width W₂). In some embodiments, distance D₁ is less than 30 nm.

The manufacturing of dielectric wall 140 (e.g., by novel methods 200) may ensure that wall 140 is exactly centered between nanoribbons 120A, 120B. In many embodiments, first thickness T_{A} between stack 121A of nanoribbons 120A and wall 140 is approximately equal to second thickness T_{B} between stack 121B of nanoribbons 120B and wall 140. In many embodiments, distance D_{A} separating stack 121A of nanoribbons 120A and wall 140 is approximately equal to distance D_{B} separating stack 121B of nanoribbons 120B and wall 140. In the context of thicknesses T_{A}, T_{B} and distances D_{A}, D_{B}, dimensions are considered approximately equal if the dimensions are within 0.5 nm.

Isolation wall 140 includes any suitable material(s), for example, a dielectric material. Wall 140 advantageously includes a low-k (low-permittivity) dielectric material. Wall 140 advantageously has an etch selectivity with other adjacent structures. In many embodiments, wall 140 includes silicon and nitrogen (e.g., in a nitride of silicon). In some embodiments, wall 140 includes silicon and oxygen (e.g., in an oxide of silicon). In some embodiments, wall 140 includes carbon and/or nitrogen, for example, in addition to silicon and oxygen.

Transistor structures 101A, 101B may be of the same or of complementary conductivity types (e.g., PMOS and/or NMOS structures 101A, 101B). For example, transistor structure 101A may be a p-type structure 101A, and transistor structure 101B may be an n-type structure 101B, or vice versa. Both of transistor structures 101A, 101B are of the same conductivity type (e.g., both PMOS structures 101A, 101B or both NMOS structures 101A, 101B).

Transistor structure 101A includes a first stack 121A of first nanoribbons 120A extending through first gate stack 125A. Transistor structure 101B includes a second stack 121B of second nanoribbons 120B extending through second gate stack 125B. Gate stacks 125A, 125B are gate structures (over nanoribbons 120A, 120B, respectively), material stacks 125 that include dielectric and conductive materials. As in the exemplary embodiment of FIG. 1A, first and second gate stacks 125A, 125B may have different first and second stack 125 compositions. The difference between the first and second compositions of stacks 125A, 125B, respectively, may be that stacks 125A, 125B include a different quantity of layers (e.g., more or different layers), similar layers but with different materials, etc. For example, first and second compositions of gate stacks 125A, 125B may differ by only (exactly) one of stacks 125A, 125B having a high-k dielectric layer 123 on a transition layer 122.

Isolation wall 140 may enable the independent processing of gate stacks 125A, 125B in structures 101A, 101B (e.g., as described at least at FIG. 2 and methods 200), which allows for stacks 125 of various compositions (e.g., having layers 122, 123, 127, etc., of different thicknesses T₁, T₂, T₃, T₄, T₅, T₆, and/or including different materials).

Much of the stacks 125A, 125B of layers around nanoribbons 120 are also on sidewalls 141, 142 of isolation wall 140. Insulator layer 123A is on sidewall 141 (of wall 140 between stacks 125A, 125B, as well as on a sidewall of wall 140 on the other side of stack 125A and corresponding electrode 126). Insulator layer 123B is on sidewall 142 (of wall 140 between stacks 125A, 125B, as well as on a sidewall of wall 140 on the other side of stack 125B and corresponding electrode 126). In transistor structure 101A, metal layer 127 is on insulator layer 123A on sidewall 141. In transistor structure 101B, metal layer 127 is on insulator layer 123B on sidewall 142. Notably, gate dielectric layers 122A, 122B on nanoribbons 120 may be absent from sidewalls 141, 142 of isolation wall 140, as in the exemplary embodiment of FIG. 1A.

First gate stack 125A includes a first dielectric stack 124A on first nanoribbons 120A, and gate stack 125A includes one or more first metal layers 127 on dielectric stack 124A. View 102 illustrates gate stack 125A on one of first nanoribbons 120A at greater magnification. View 102 shows an embodiment having multiple layers 127 on stack 124A. First dielectric stack 124A includes dielectric layers 122A (on first nanoribbons 120A) and insulator layers 123A (on dielectric layers 122A and around first nanoribbons 120A). First gate stack 125A may also include a metal (e.g., fill) layer 128 on liner layer 127.

Second gate stack 125B includes a second dielectric stack 124B on second nanoribbons 120B, and gate stack 125B includes one or more second metal layers 127 on dielectric stack 124B. View 103 illustrates gate stack 125B on one of second nanoribbons 120B at greater magnification. Second dielectric stack 124B includes dielectric layers 122B (on second nanoribbons 120B) and insulator layers 123B (on dielectric layers 122B and around second nanoribbons 120B). Second gate stack 125B may also include a metal (e.g., fill) layer 128 on liner layer 127.

Dielectric layers 122 (e.g., layers 122A, 122B) may include any suitable material(s) and may have any suitable thickness(es). Layers 122A, 122B are on nanoribbons 120 in transistor structures 101A, 101B, respectively, and may provide protection to nanoribbons 120, e.g., during processing. For example, layers 122A, 122B may be passivation layers 122A, 122B, e.g., of a native oxide of a material in nanoribbons 120. In many embodiments, dielectric layers 122 include silicon and oxygen. Layers 122A, 122B may be transition layers 122 between nanoribbons 120 and other layers (such as layers 123, etc.) over layers 122. In some embodiments, dielectric layers 122A, 122B have thicknesses T₁, T₂ less than thicknesses of other layers over layers 122A, 122B. In many embodiments, dielectric layers 122A have a thickness T₁ greater than (or less than) a thickness T₂ of dielectric layers 122B. For example, layer 122A may have a thickness T₁ of 1 nm or less and layer 122B may have a thickness T₂ of 1.3 nm or more. In some embodiments, one of layers 122A, 122B includes a material not included in the other of layers 122A, 122B. Layers 122 may include other suitable materials. Different thicknesses T₁ or T₂ (or different material compositions) of layers 122A, 122B may provide different threshold voltages V_{T} for transistor structures 101A, 101B. Different thicknesses T₁ or T₂ of layers 122A, 122B may provide different thicknesses of nanoribbons 120 in transistor structures 101A, 101B.

Insulator layers 123 (e.g., layers 123A, 123B) may include any suitable material(s) and may have any suitable thickness(es). Layers 123A, 123B are on transition layers 122A, 122B in transistor structures 101A, 101B, respectively. In many embodiments, insulator layers 123A, 123B have thicknesses T₃, T₄ greater than thicknesses T₁, T₂ of layers 122A, 122B on nanoribbons 120. Insulator layers 123 may be dielectric layers 123. For example, layers 123A, 123B advantageously include one or more high-k dielectric materials, which may provide design flexibility and/or superior characteristics (such as electrical characteristics) when deployed with, or instead of, other materials.

Layers 123 (e.g., high-k layers 123A, 123B) may allow for a greater transconductance gₘ (e.g., for a same voltage on gate electrode 126 and same thickness T₃ or T₄) in transistor structures 101A, 101B. High-k layers 123 may allow for greater total thicknesses (e.g., thickness T₁ plus thickness T₃ in stack 125A or thickness T₂ plus thickness T₄ in stack 125B) of dielectric over nanoribbons 120, and so may enable low leakage currents in structures 101A, 101B (e.g., for a same voltage on gate electrode 126 while maintain a same transconductance gₘ). High-k layers 123A, 123B may enable low leakage currents in structures 101A, 101B, e.g., with a lower voltage on gate electrode 126 and a same thickness T₃ or T₄. In many embodiments, insulator layers 123A have a thickness T₃ greater than (or less than) thickness T₄ of insulator layers 123B. For example, layer 123A may have a thickness T₃ of 1.3 nm or less and layer 122B may have a thickness T₄ of 1.8 nm or more. Different thicknesses T₃ or T₄ (or different material compositions) of layers 123A, 123B may provide different threshold voltages V_{T} for transistor structures 101A, 101B.

Insulator layers 123 may include any suitable material(s). In many embodiments, insulator layers 123 include hafnium and oxygen. In some embodiments, insulator layers 123 include zirconium and oxygen. In some embodiments, insulator layers 123 include hafnium, zirconium, and oxygen. In some embodiments, insulator layers 123A, 123B have different material compositions. In some embodiments, for example, insulator layers 123A (or layers 123B) include hafnium and zirconium, and insulator layers 123B (or layers 123A) include neither, or only one, of hafnium and zirconium (e.g., hafnium but not zirconium, or zirconium but not hafnium). In some embodiments, layers 123A, 123B both include hafnium, zirconium, and oxygen (HZO, e.g., in hafnium zirconate or hafnium zirconium oxide), but at different elemental ratios. The material compositions of one or both of layers 123A, 123B (e.g., the ratio of hafnium to zirconium) may be varied to increase a relative permittivity of layer 123A and/or 123B (e.g., from about 1:1 to about 2:1 or more). In some embodiments, a dopant (e.g., yttrium) is added to one or both of layers 123A, 123B to increase a relative permittivity of layer 123A and/or 123B (e.g., by increasing a proportion of higher-permittivity dielectric phase in layer(s) 123). Either or both of layers 123A, 123B may include one or more of various elements, such as hafnium, zirconium, silicon, oxygen, titanium, tantalum, lanthanum, aluminum, barium, strontium, yttrium, lead, scandium, niobium, and zinc. Layers 123 may include other suitable materials.

First and second gate stacks 125A, 125B may include a dipole dopant. In some embodiments, one of first and second gate stacks 125A, 125B includes a dipole dopant not present in the other of gate stacks 125A, 125B. In some embodiments, first and second gate stacks 125A, 125B include a same dipole dopant, but the dipole dopant is present at a first height (e.g., of a sum of thicknesses T₁, T₃) from nanoribbons 120A in stack 121A greater (or lesser) than a second height (e.g., of a sum of thicknesses T₂, T₄) from nanoribbons 120B in stack 121B. The same dipole dopant may be within different layers 122, 123 (or at a different interface of layers 122, 123) in the different dielectric stacks 124A, 124B.

Gate electrodes 126 (and gate stacks 125A, 125B) may include one or more metal layers 127, 128. Gate electrodes 126, together with first and second dielectric stacks 124A, 124B, form first and second gate structures for electrostatically controlling the conduction of nanoribbons 120 (and transistor structures 101A, 101B). Layers 127, 128 may be workfunction metal (WFM) layers 127, 128, e.g., to (e.g., independently) influence threshold voltages V_{T} of transistor structures 101A, 101B. Layers 127 may be conformal, liner layers 127 around nanoribbons 120 and dielectric stacks 124, e.g., with a first metal layer 127 on insulator layer 123A around each of nanoribbons 120A in structure 101A and a second metal layer 127 on insulator layer 123B around each of nanoribbons 120B in structure 101B. Transistor structure 101A and gate stack 125A may include one or more metal layers 127 in electrode 126. Transistor structure 101B and gate stack 125B may include one or more metal layers 127 in electrode 126.

Liner layers 127 in structures 101A, 101B may have different thicknesses T₅, T₆, respectively, for example, with a thickness T₅ (or thickness T₆) greater than a thickness T₆ (or thickness T₅) and having a correspondingly larger impact on the threshold voltage V_{T} of transistor structure 101A (or structure 101B). Layers 127 in structures 101A, 101B may have different material compositions. Fill layers 128 in structures 101A, 101B may have different material compositions. Layers 127, 128 may include any suitable material(s), including non-metals. In many embodiments, layers 127 include nitrogen (e.g., in a metal nitride) or carbon (e.g., in a metal carbide). In some such embodiments, layers 127 include nitrogen and titanium, molybdenum, or tantalum. In some embodiments, a first layer 127 on a dielectric stack 124 includes titanium and nitrogen, and a second layer 127 on first layer 127 includes nitrogen and tantalum or molybdenum. In some embodiments, layer 127 includes titanium, aluminum, and carbon. In many embodiments, layer 128 includes tungsten.

Nanoribbons 120A in stack 121A may be the same or different than nanoribbons 120B in stack 121B. For example, nanoribbons 120 in the different stacks 121A, 121B may be of the same or different materials, have the same or different thicknesses, etc. Nanoribbons 120 may have any suitable width (and may be, e.g., nanowire nanoribbons 120 or nanosheet nanoribbons 120). Nanoribbons 120 may be of any suitable (e.g., semiconducting) material(s). In many embodiments, nanoribbons 120 include silicon. In some embodiments, at least some of nanoribbons 120 include germanium. For example, in some embodiments, transistor structure 101A is an NMOS structure 101A, nanoribbons 120A are predominantly silicon, transistor structure 101B is a PMOS structure, and nanoribbons 120B include silicon and germanium. In at least some such embodiments, nanoribbons 120A, 120B are at different (e.g., staggered) heights. In other embodiments, transistor structures 101A, 101B are of the same conductivity type but, e.g., with different threshold voltages V_{T}. In the exemplary embodiments of FIG. 1A, stacks 121A, 121B each have four nanoribbons 120A, 120B, but stacks 121A, 121B may have any suitable number of nanoribbons 120A, 120B. In some embodiments, stacks 121A, 121B each have three (or fewer) nanoribbons 120A or 120B. In other embodiments, stacks 121A, 121B each have five (or more) nanoribbons 120A or 120B.

Gate vias 129 are metallization structures that couple (e.g., electrically couple) gate electrodes 126, for example, with an interconnect network (not shown) above transistor structures 101. Vias 129 may include any suitable material(s), including non-metals. Vias 129 may include multiple layers of metals, for example, a liner (e.g., barrier or seed) layer around a fill layer. Gate vias 129 are through a dielectric layer 149 over transistor structures 101A, 101B. Dielectric layer 149 may be of any suitable material, such as a low-k dielectric material.

Substrate 199 may include any suitable material or materials. Substrate 199 may be an IC substrate, such as an IC die or wafer. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. Transistor structures 101 may be over a dielectric layer over other (e.g., semiconductor) materials.

FIG. 1B illustrates x-z view 105 longitudinally through nanoribbons 120 coupled between source and drain bodies 110 in transistor structure 101 in device 100, in accordance with some embodiments, as well as y-z view 104, e.g., for reference. One of stacks 121 of nanoribbons 120 is shown extending between, and coupling, source and drain bodies 110. Any of transistor structures 101 in view 104 may be either of structures 101A, 101B, as described at FIG. 1A. For example, gate stack 125 in view 105 may be either of stacks 125A, 125B, as described at FIG. 1A. Dielectric wall 140 (not shown in view 105) may be in front of or behind the viewing plane of view 105.

Source and drain bodies 110 are electrically and physically coupled to ends of nanoribbons 120 (e.g., channel regions). Source and drain bodies 110 may be impurity doped regions, e.g., regions of semiconductor material doped with one or more electrically active impurities and having increased charge-carrier availabilities and associated conductivities. Bodies 110 in different transistor structures 101 may be doped with opposite type (e.g., n- or p-type) or similar type dopants. Source and drain bodies 110 may include a predominant semiconductor material, and one or more n-dopants (such as phosphorus, arsenic, or antimony) or p-type impurities (such as boron or aluminum). Other dopant materials may be used. Any suitable means of formation may be used. Bodies 110 may be epitaxially grown semiconductor regions, for example, of a Group IV semiconductor material (e.g., Si, Ge, SiGe, GeSn alloy). Other semiconductor materials may be employed. Bodies 110 may be substantially crystalline. Source and drain bodies 110 may be polycrystalline or substantially monocrystalline, e.g., having long-range order at least adjacent ends of nanoribbons 120 (e.g., to both sides of bodies 110) and merging or joining into a unitary body with few grain boundaries.

Source and drain bodies 110 are electrically and physically coupled to opposite ends of nanoribbons 120 (e.g., channel regions). In many embodiments, transistor structures 101 are each physically symmetrical about nanoribbons 120 (e.g., channel regions) and gate electrodes 126, and identifiers “drain” and “source” for bodies 110 may be reversed interchangeably in many contexts. However, the classification of source and drain bodies 110 may be by the electrical relationships of transistor structures 101 and bodies 110 to other components in a given circuit (e.g., and the consequent direction of current flow through structures 101 and bodies 110). Some source and drain bodies 110 may simultaneously be a source body 110 in one transistor structure 101 and a drain body 110 in another transistor structure 101.

Source and drain contact vias 119 are metallization structures that couple (e.g., electrically couple) bodies 110, for example, with an interconnect network (not shown) above transistor structures 101. Contact vias 119 may include any suitable material(s), including non-metals. For example, vias 119 may include an interface (e.g., silicide) layer on bodies 110. Vias 119 may include multiple layers of metals, for example, a liner (e.g., barrier or seed) layer around a fill layer. Vias 119 are through dielectric layer 149 over transistor structures 101A, 101B and through dielectric layer 114 over bodies 110. Dielectric layer 114 may be of any suitable material, such as a low-k dielectric material.

Spacers 147, 148 are dielectric walls, e.g., isolation structures of an insulator material (such as a low-k dielectric), adjacent gate electrodes 126. Dimple spacers 148 provide isolation between electrodes 126 and bodies 110. Spacers 147 provide isolation between electrodes 126 and bodies 110 and contact vias 119 over bodies 110. Spacers 147, 148 may be of the same or different dielectric materials. Dielectric spacers 147, 148 may include any suitable material(s). In many embodiments, spacers 147 and/or 148 include oxygen and/or nitrogen (e.g., in an oxide, nitride, or oxynitride of silicon). In many embodiments, spacers 147 and/or 148 have etch selectivities with other dielectric structures. In some embodiments, spacers 147 and/or 148 include carbon, for example, to provide etch selectivities with dielectric walls 140, etc.

FIG. 1C shows dielectric wall 140 between gate stacks 125A, 125B and, notably, not between source or drain bodies 110 in both of transistor structures 101A, 101B, in accordance with some embodiments. Dielectric walls 145 are between source or drain bodies 110. View 104 illustrates a cross-sectional, y-z profile view through dielectric walls 145 and source or drain bodies 110A, 110B in transistor structures 101A, 101B. Nanoribbons 120 are in front of or behind bodies 110, not in the viewing plane, and are shown (e.g., with dashed outlines) for reference. View 106 shows a cross-sectional, x-y plan view through dielectric walls 140, 145, source or drain bodies 110, and gate stacks 125 in transistor structures 101A, 101B. Notably, dielectric walls 145 are between adjacent pairs of source or drain bodies 110 (e.g., bodies 110A, 110B), and each body 110 is between a pair of dielectric walls 145. Each wall 140 has sidewalls 141, 142 on different gate stacks 125A, 125B, and each stack 125 is (on and) between sidewalls 141, 142 of different dielectric walls 140. Each wall 145 has sidewalls on different source or drain bodies 110, and each body 110 is (on and) between sidewalls of different dielectric walls 145. Gate stacks 125A, 125B are as described (e.g., at least at FIGS. 1A, 1B), for example, having electrodes 126 and dielectric stacks in transistor structures 101A, 101B.

View 104 illustrates a profile view of device 100 at a y-z viewing plane through dielectric walls 145 and source or drain bodies 110A, 110B. Walls 145 may not be self-aligned between bodies 110. In many embodiments, centerlines (CL, e.g., centerline CL₄) of walls 145 are not aligned with centerlines of walls 140 (as described at view 106) and are not centered between nanoribbons 120 (as if extended into bodies 110). Distance D₁ (as described at FIG. 1A) separates stacks 121 of nanoribbons 120. In many embodiments, distance D_{C} separating wall 145 and stack 121A of nanoribbons 120A (as if extended in the x-directions, into a body 110) is not equal to distance D_{D} separating wall 145 and stack 121B of nanoribbons 120B (as if extended in the x-directions, into a body 110). In the context of distances D_{C}, D_{D}, dimensions are considered approximately equal if the dimensions are within 0.5 nm. In the exemplary embodiment of FIG. 1C, distance D_{D} is shorter than distance D_{C}. Source or drain bodies 110A, 110B are on sidewalls of walls 145.

Wall 145 has opposing sidewalls and width W₃ (or width W₄) separating sidewalls of wall 145. In some embodiments, source or drain bodies 110 are on (e.g., grown onto) walls 145, and width W₃ (or width W₄) separates bodies 110A, 110B in transistor structures 101A, 101B (respectively). Dielectric wall 145 (e.g., the opposing sidewalls of wall 145) are not vertical. For example, the sidewalls of wall 145 are both more than one degree from vertical. In many embodiments, widths W₃, W₄ of wall 145 are not equal (e.g., more than 1 nm apart, with vertical tapering). Width W₃ is defined as the width of wall 145 at a top of wall 145, above the stacks of nanoribbons 120A, 120B. Width W₄ is defined as the width of wall 145 at a bottom of bodies 110, e.g., where wall 145 meets substrate 199 at a bottom of body 110, below the stacks of nanoribbons 120A, 120B. Wall 145 includes a width W_{B} at a height between the heights of widths W₃, W₄ (for example, at a midpoint of height H) separating the opposing sidewalls of wall 145. In many embodiments, width W_{B} of dielectric wall 145 is not equal to widths W₃, W₄. Dielectric wall 145 may include any suitable material(s), for example, a low-k dielectric. In many embodiments, walls 140, 145 include the same or similar materials, e.g., a nitride (such as a nitride of silicon). In some embodiments, walls 140, 145 have the same or similar material compositions.

Plan view 106 has a cross-sectional x-y viewing plane through walls 140, 145, source or drain bodies 110A, 110B, and gate electrodes 126 of transistor structures 101A, 101B (e.g., vertically between nanoribbons 120, for example, at a vertical middle of stacks 121A, 121B). Nanoribbons 120 (e.g., nanoribbons 120A, 120B) not in the viewing plane are shown (e.g., for reference) with dashed lines. Source and drain bodies 110 are electrically and physically coupled to opposite ends of channel-region nanoribbons 120.

As shown in view 106, dielectric wall 140 is between stacks 121A, 121B of first and second nanoribbons 120A, 120B, and gate stacks 125A, 125B. Dielectric wall 140 extends between spacers 147. Gate dielectric layer 123 is on electrodes 126 and on dielectric wall 140 (e.g., at sidewalls 141, 142) and spacers 147. Dielectric wall 140 is an isolation structure, e.g., providing electrical isolation between electrodes 126. Other gate electrodes 126, etc., not shown, are in other transistor structures 101 just beyond edges of view 106 (e.g., in the x-directions).

Wall 140 includes a width W_{A} at a height between the heights of widths W₁, W₂ (for example, at a midpoint of height H of FIG. 1A) separating sidewalls 141, 142. In many embodiments, width W_{A} of dielectric wall 140 is equal to widths W₁, W₂.

Spacers 147 are isolation structures, e.g., of insulator material (such as a low-k dielectric), adjacent gate electrodes 126 and source or drain bodies 110. Spacers 147 provide isolation (e.g., electrical isolation) between electrodes 126 and bodies 110.

Dielectric walls 140, 145 are between spacers 147 (dielectric walls orthogonal to walls 140). Dielectric walls 140 are between gate stacks 125A. Dielectric walls 145 are between source or drain bodies 110. Centerlines of various dielectric walls (e.g., walls 140, 145; spacers 147) are labelled and used to describe structural relationships. Each dielectric wall 140 (e.g., wall 140 having centerline CL₁) extends in the x-directions between a pair of spacers 147 (e.g., spacers 147 having centerlines CL₂, CL₃), with opposing ends of the dielectric wall 140 on the pair of spacers 147. Each dielectric wall 145 (e.g., walls 145 having centerlines CL₄, CL₅) extends in the x-directions between a pair of spacers 147, with opposing ends of each dielectric wall 145 on the corresponding pair of spacers 147. Spacers 147 (e.g., with centerlines CL₂, CL₃, CL₆, CL₇) extend laterally in the y-directions.

Dielectric walls 140 in a device 100 may be self-aligned between stacks 121A, 121B and with other walls 140. A first dielectric wall 140 (e.g., wall 140 with centerline CL₁) between a first pair of stacks 121A, 121B is aligned with a second dielectric wall 140 (e.g., wall 140 with centerline CL₁₁) between a second pair of stacks 121A, 121B aligned with the first pair of stacks 121A, 121B. For example, centerlines CL₁, CL₁₁ of first and second walls 140 are collinear, midway between nanoribbons 120A, 120B of stacks 121A, 121B. First and second walls 140 are centered between nanoribbons 120A, 120B of stacks 121A, 121B.

Walls 145 are not necessarily so aligned, for example, due to lithographic registration errors. Walls 145 may be somewhat aligned with other walls 145, but are not centered between nanoribbons 120A, 120B of stacks 121A, 121B. For example, source or drain bodies 110A, 110B fill the spaces between walls 145, and source or drain bodies 110A, 110B are different sizes (e.g., in the y-dimensions, due to misregistered walls 145).

First nanoribbons 120A (in a stack 121A) extend in the x-directions through first gate stack 125A between first and third source or drain bodies 110A, coupled with first and third bodies 110A. Second nanoribbons 120B (in a stack 121B) extend in the x-directions through second gate stack 125B between second and fourth source or drain bodies 110B, coupled with second and fourth bodies 110B. Dielectric walls 145 with centerlines CL₄, CL₅ extend laterally in the x-directions. Dielectric wall 145 with centerline CL₄ extends (and provides isolation) between first source or drain body 110A and second source or drain body 110B. Dielectric wall 145 with centerline CL₅ extends (and provides isolation) between third source or drain body 110A and fourth source or drain body 110B. Spacers 147 with centerlines CL₂, CL₃ are between spacers 147 with centerlines CL₆, CL₇. First and second source or drain bodies 110A, 110B are between the spacers 147 with centerlines CL₂, CL₆. Third and fourth source or drain bodies 110A, 110B are between spacers 147 with centerlines CL₃, CL₇.

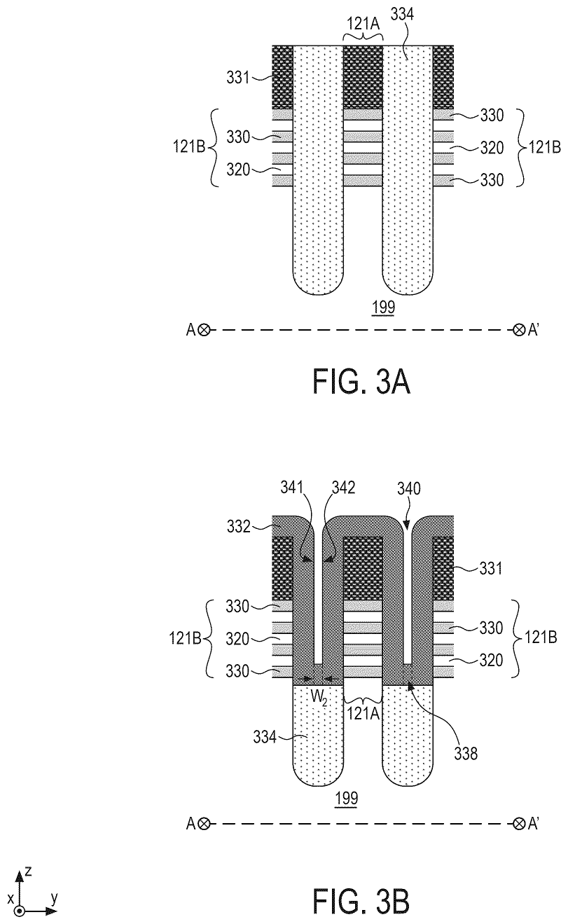

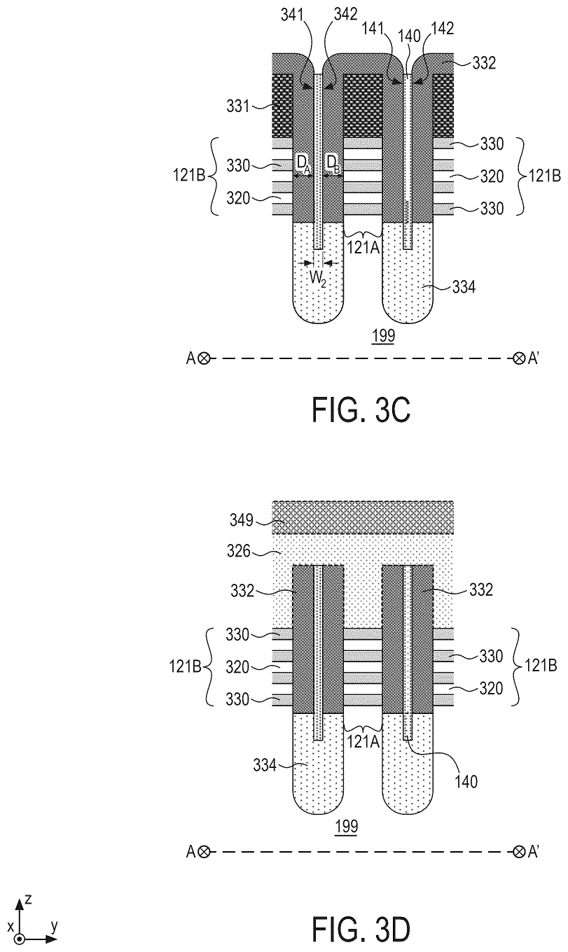

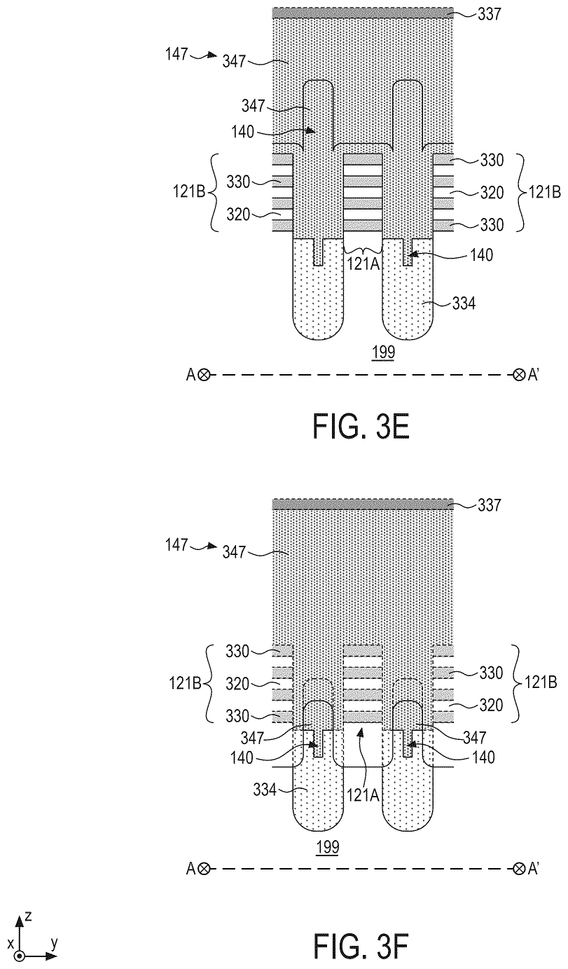

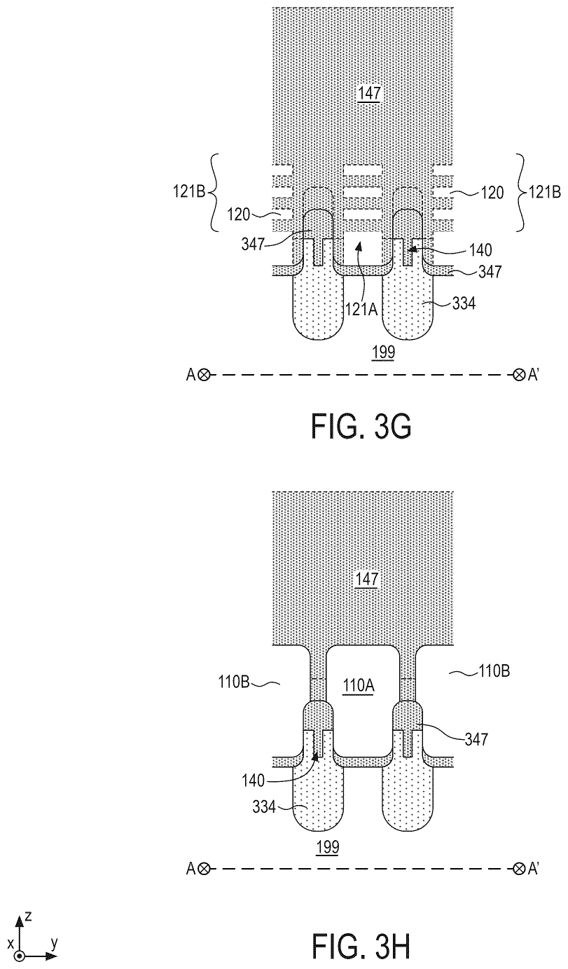

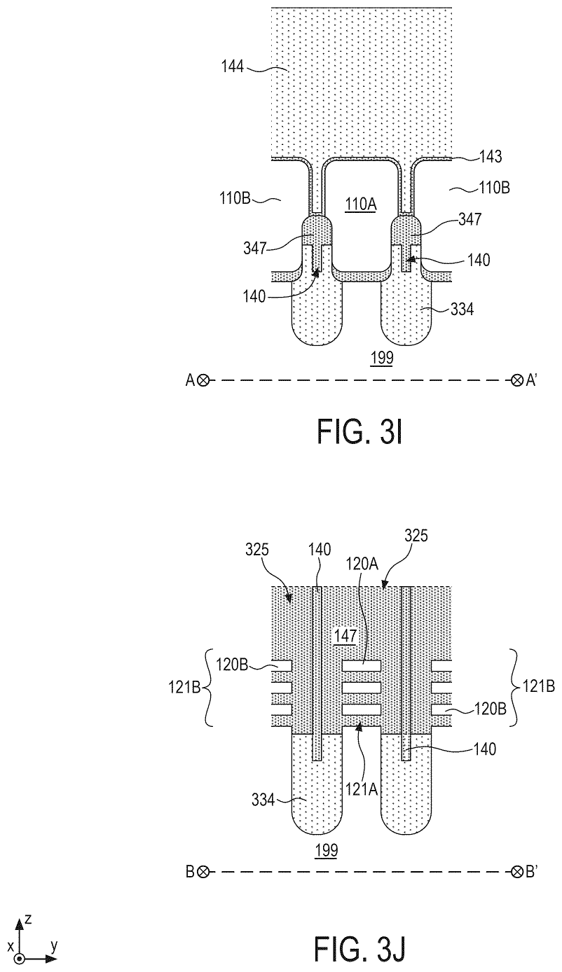

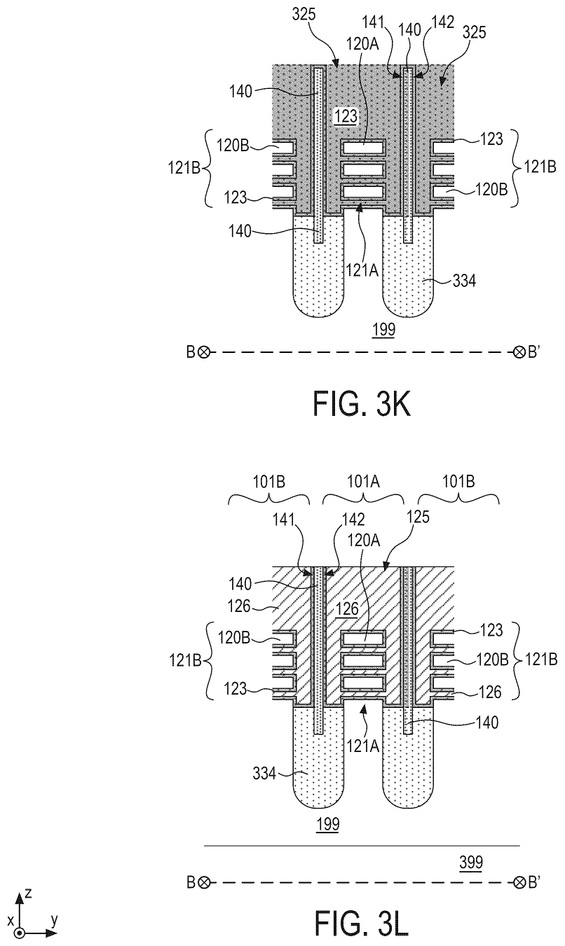

FIG. 1D illustrates dielectric wall 140 between gate stacks 125A, 125B and, notably, not between source or drain bodies 110 in both of transistor structures 101A, 101B, in accordance with some embodiments. View 104 illustrates a cross-sectional, y-z profile view through dielectric material 144 and bodies 110 (e.g., bodies 110A, 110B) in transistor structures 101A, 101B. Nanoribbons 120 are in front of or behind bodies 110, not in the viewing plane, and are shown (e.g., with dashed outlines) for reference. View 106 shows a cross-sectional, x-y plan view through dielectric walls 140, source or drain bodies 110, and gate stacks 125 in transistor structures 101A, 101B. Each wall 140 has sidewalls 141, 142 on different gate stacks 125A, 125B, and each stack 125 is (on and) between sidewalls 141, 142 of different dielectric walls 140. View 106 shows the orientations of viewing planes A-A′ and B-B′, which will be employed in FIGS. 3A-3L to illustrate various stages of manufacture, e.g., during methods 200. Viewing plane A-A′ is through a source-drain region, e.g., with source or drain bodies 110. Viewing plane B-B′ is through a gate region, e.g., with gate electrodes 126.

View 104 illustrates a profile view of device 100 at a y-z viewing plane through dielectric material 144 and source or drain bodies 110A, 110B, which are not separated by dielectrics walls (such as walls 145 of FIG. 1C). In some embodiments, dielectric material 144 is on and between dielectric layers 143 on bodies 110. In many such embodiments, material 144 is a low-k dielectric material 144, e.g., for providing electrical isolation between source or drain bodies 110. In some embodiments, dielectric material 144 includes oxygen, e.g., in an oxide (such as an oxide of silicon). Layer 143 may provide an etch selectivity and, for example, protection for bodies 110 from an oxide material 144. In some embodiments, dielectric layer 143 includes nitrogen, e.g., in a nitride (such as a nitride of silicon).

Trench isolations 194 may be between source or drain bodies 110, and isolation structures 174 may be in and over isolations 194, between bodies 110. Isolations 194 may include a low-k dielectric material, for example, to provide good electrical isolation between bodies 110, etc. In some embodiments, dielectric material of isolation 194 includes oxygen, e.g., in an oxide (such as an oxide of silicon). Structures 174 may be continuous with walls 140 and/or spacers 147, e.g., having different portions with different compositions, one continuous with walls 140 and another continuous with spacers 147. In many embodiments, structure 174 includes nitrogen, e.g., in a nitride (such as a nitride of silicon). In some embodiments, structure 174 includes carbon, e.g., as a dopant in an oxide, nitride, or oxynitride (for example, of silicon).

View 106 shows a x-y layout view of dielectric walls 140 between gate stacks 125, as well as isolation material 144 between source or drain bodies 110, in transistor structures 101A, 101B. Notably, adjacent source or drain bodies 110 are isolated by dielectric material 144. In some embodiments, a dielectric layer 143 is on bodies 110, between dielectric material 144 and bodies 110 (for example, a liner layer 143 on bodies 110 and spacers 147, enclosing dielectric material 144). Gate stacks 125A, 125B are as described (e.g., at least at FIGS. 1A, 1B), for example, having electrodes 126 and dielectric stacks in transistor structures 101A, 101B.

Dielectric walls 140 are between gate stacks 125A, 125B and between spacers 147 (dielectric walls orthogonal to walls 140). Each dielectric wall 140 extends in the x-directions between a pair of spacers 147 (which extend in the y-directions), with opposing ends of the dielectric wall 140 on the pair of spacers 147. First nanoribbons 120A (e.g., through gate stack 125A adjacent wall 140 with centerline CL₁) are coupled with a first source or drain body 110A. Spacer 147 with centerline CL₂ is between first gate stack 125A and the first source or drain body 110A. Second nanoribbons 120B (e.g., through gate stack 125B adjacent wall 140 with centerline CL₁) are coupled with a second source or drain body 110B. Spacer 147 with centerline CL₂ is between second gate stack 125B and the second source or drain body 110B. A first dielectric material 144 is between the first and second source or drain bodies 110A, 110B. A layer 143 of a second dielectric material is on the first and second source or drain bodies 110A, 110B. The layer 143 is on spacer 147 with centerline CL₂. The layer 143 is between the first dielectric material 144 and spacer 147 with centerline CL₂. The layer 143 is between the first dielectric material 144 and the first source or drain body 110A. The layer 143 is between the first dielectric material 144 and the second source or drain body 110B.

FIG. 2 is a flow chart of methods 200 for forming vertical, self-aligned dielectric walls for gate tub isolation, in accordance with some embodiments. Methods 200 include operations 210-290. Some operations shown in FIG. 2 are optional. Additional operations may be included. FIG. 2 shows an example sequence, but the operations can be done in other orders as well, and some operations may be omitted. Some operations can also be performed multiple times before other operations are performed. For example, multiple etches may be performed adjacent the patterned mask material before forming gate structures. Some operations may be included within other operations so that the number of operations illustrated FIG. 2 is not a limitation of the methods 200.

FIGS. 3A, 3B, 3C, 3D, 3E, 3F, 3G, 3H, 3I, 3J, 3K and 3L illustrate cross-sectional profile views of IC device 100 having vertical, self-aligned dielectric walls 140 between gate structures, at various stages of manufacture, in accordance with some embodiments. FIGS. 3A-3L show possible examples of intermediate structures during an embodiment of a practice of methods 200 of FIG. 2.

FIG. 3A shows stacks 121A, 121B of material layers 320, 330 in a substrate 199 in a workpiece or IC device 100, in accordance with some embodiments, for example, prior or during a performance of forming operation 210. A single stack 121A of material layers 320, 330 is between stacks 121B of material layers 320, 330. In many embodiments, substrate 199 includes many parallel stacks 121A, 121B. In some embodiments, a hardmask 331 is over stacks 121A, 121B. In some embodiments, a trench isolation 334 is between stacks 121A, 121B, for example, one of many trench isolations 334 between many parallel stacks 121A, 121B. Trench isolation 334 may be recessed down to below stacks 121A, 121B, e.g., to expose material layers 320, 330.

Viewing plane A-A′ of FIGS. 3A-3I is a cross-section through the eventual location of source and drain bodies. FIGS. 3J-3L will use viewing plane B-B′, a cross-section through the eventual location of gate electrodes.

Returning to FIG. 2, methods 200 begin at operation 210 with forming sacrificial sidewalls between first and second stacks of material layers. Sacrificial sidewalls may be formed by any suitable means and of any suitable material(s). In many embodiments, opposing first and second sacrificial sidewalls are formed by (e.g., conformally) depositing a sacrificial layer over and between the first and second stacks of material layers. The sacrificial layer may be conformally formed by a well-controlled deposition method, such as an ALD, to carefully set the thickness of the conformal layer, which in turn determines the width of the gap between the first and second sacrificial sidewalls. An ALD deposition may be perfectly conformal and may enable precise control of the sacrificial layer thickness (e.g., to a molecular-layer thickness) and, therefore, of the width of the gap between the first and second sacrificial sidewalls. A conformally deposited sacrificial material may form lateral (e.g., horizontal) portions between the sacrificial sidewalls, for example, over tops of the stacks of material layers and in trenches between the stacks of material layers.

The (e.g., conformally deposited) sacrificial material may be any suitable sacrificial material, for example, having an etch selectivity with a subsequently deposited dielectric material (e.g., that will form the dielectric wall isolation between material stacks and gate structures). In many embodiments, the conformally deposited sacrificial material includes silicon and oxygen, for example, with carbon and/or nitrogen. In many embodiments, the conformally deposited sacrificial material includes aluminum and oxygen.

The first and second stacks of material layers may be formed (or received, as is) on or in a substrate, such as an IC die or wafer, e.g., much as described of substrate 199 at FIG. 1A. The stacks of material layers may be formed by any suitable means. In many embodiments, the material layers are alternating, substantially planar layers of channel and sacrificial materials, e.g., with the channel layers to be retained and the sacrificial layers to be removed from between the channel layers (and, for example, to be replaced by a gate structure between and around the channel layers). In some embodiments, the channel materials in first stack are sacrificial materials in the second stack, and vice versa. For example, in some embodiments, the first and second stacks of material layers are layers of silicon and silicon germanium, the silicon layers are retained as channel layers in the first stack, and the silicon germanium layers are retained as channel layers in the second stack.

FIG. 3B illustrates sacrificial layer 332 conformally over and between first and second stacks 121A, 121B of material layers 320, 330 in workpiece or device 100, in accordance with some embodiments, for example, following a performance of forming operation 210. First and second sidewalls 341, 342 are between stacks 121A, 121B of material layers 320, 330. A lateral portion 338 (e.g., between dashed lines) of sacrificial layer 332 is on trench isolation 334, between stacks 121A, 121B and first and second sidewalls 341, 342. A gap 340 may be between first and second sidewalls 341, 342 and may have a width W₂.

Returning to FIG. 2, methods 200 continue at operation 220 with optionally removing a lateral portion of the sacrificial layer by etching between the first and second sidewalls. The lateral portion may be removed by any suitable means. The lateral portion may be between the stacks of material layers, e.g., over trench isolation at a bottom of a trench between the stacks. In many embodiments, the lateral portion is removed by a dry, anisotropic etch between the first and second sidewalls, for example, a reactive ion etch (RIE), such as a deep RIE. The vertical sidewalls of the sacrificial layer may direct the downwards etch to the lateral portion at a bottom of a trench between the stacks of material layers. An anisotropic etch downwards, between the sidewalls, may ensure that the gap between the sidewalls is perfectly vertical and may provide further control of the width of the gap (if desired). The anisotropic etch may continue through the lateral portion and etch further into the substrate, e.g., into trench isolation between the stacks of material layers. With the lateral portion removed, the substrate and the (e.g., conformal) sacrificial layer may be prepared for the fabrication of the dielectric wall.

Returning to FIG. 2, methods 200 continue by forming a dielectric wall at operation 230. The dielectric wall may have third and fourth sidewalls on and between the first and second (e.g., sacrificial) sidewalls. The dielectric wall may be formed by any suitable means and of any suitable material(s). In many embodiments, the dielectric wall is formed by depositing a dielectric layer over and between the first and second sacrificial sidewalls and over and between the first and second stacks of material layers. For example, the dielectric layer may be conformally formed by a well-controlled deposition method, such as an ALD, to carefully and perfectly conformally deposit the dielectric layer on and between the first and second sacrificial sidewalls. An ALD deposition may enable the precise control necessary to perfectly fill the width of the gap between the first and second sacrificial sidewalls. The width of a conformally deposited dielectric layer may need to be at least half of the width of the gap between the first and second sacrificial sidewalls to fill the gap perfectly. Once the gap is filled, more of the dielectric layer may be conformally deposited, e.g., over the conformally deposited sacrificial layer. In some embodiments, the dielectric layer may be recessed (for example, by a selective etch) from over the conformally deposited sacrificial layer.

The dielectric wall may be much as described of wall 140 (e.g., at least at FIGS. 1A-1D). For example, the dielectric wall may be exactly centered between the first and second material layer stacks, e.g., with a first distance between the dielectric wall and the first stack equal to a second distance between the dielectric wall and the second stack. The dielectric wall may include any suitable material(s). In many embodiments, the dielectric wall includes silicon and nitrogen (e.g., in a nitride of silicon). In some embodiments, the dielectric wall includes silicon and oxygen (e.g., in an oxide of silicon). In some embodiments, the dielectric wall includes carbon and/or nitrogen, for example, in addition to silicon and oxygen.

FIG. 3C shows dielectric walls 140 between stacks 121A, 121B of material layers 320, 330 and between and on sidewalls 341, 342 of sacrificial layer 332 in workpiece or device 100, in accordance with some embodiments, for example, following a performance of removing and forming operations 220 and 230. Dielectric walls 140 are exactly centered between material layer stacks 121, e.g., with distance D_{A} separating wall 140 and stack 121A equal to distance D_{B} separating wall 140 and stack 121B. No lateral portion 338 of sacrificial layer 332 is present on trench isolation 334, between stacks 121A, 121B and between first and second sidewalls 341, 342. Dielectric walls 140 extend down between and on sidewalls 341, 342 of (now-interrupted) sacrificial layer 332 and down into trench isolation 334. Dielectric walls 140 have sidewalls 141, 142 on sidewalls 341, 342 of layer 332. Dielectric walls 140 may have a width W₂ (e.g., in trench isolation 334), and width W₂ may be larger than width W₂ at FIG. 3B, e.g., after an etch between sidewalls 341, 342 at removing operation 220. In some embodiments (for example, without a selective etch of the dielectric layer forming wall 140), a layer of the material of dielectric wall 140 is conformally over sacrificial layer 332 and tops of stacks 121 of layers 320, 330.

Returning to FIG. 2, methods 200 continue with removing upper portions of the sacrificial and dielectric layers at operation 240. The upper portions of the (e.g., conformal) sacrificial and dielectric layers may be lateral or horizontal portions over the first and second stacks of material layers. The upper portions of the sacrificial and dielectric layers may be removed by any suitable means, for example, by a chemical-mechanical planarization (or polish, CMP). The upper lateral portions may be on a hardmask over the stacks of material layers, and the removal of the upper lateral portions may expose the hardmask over the stacks of material layers. In some such embodiments, the exposed hardmask material may be removed, e.g., by a selective etch.

Returning to FIG. 2, methods 200 continue at operation 250 by patterning a mask material over portions of the dielectric wall and the stacks of material layers. The mask material may be deployed to cover (e.g., channel) material layers that will be in and through gate and spacer portions of the eventual transistors. The mask material may be patterned (e.g., deposited and retained) over first portions of the dielectric wall and first portions of the first and second stacks of material layers that are to be protected and retained. The mask material may be patterned to not cover second portions of the dielectric wall and second portions of the first and second stacks of material layers, as well as first and second portions of the sacrificial layer (e.g., adjacent second portions of the dielectric wall not covered by the mask material, between the dielectric wall and the second stack of material layers).

The mask material may be patterned by any suitable means and of any suitable material(s). In many embodiments, the mask material is patterned lithographically, for example, with an anisotropic etch. In many embodiments, the mask material includes polycrystalline silicon or tungsten., e.g., as a dummy-gate material. An additional mask material may be over such a dummy-gate material, such as a hardmask material (e.g., to provide an etch selectivity). In some embodiments, a dummy-gate material is blanket deposited over the substrate (e.g., over and between dielectric walls, etc.), an additional mask material is patterned over the dummy-gate material, and dummy-gate material not covered by the patterned, additional mask material is removed.

Returning to FIG. 2, methods 200 continue at operation 260 with removing portions of the sacrificial layer adjacent the uncovered portions of the dielectric wall. The sacrificial layer portions may be removed by any suitable means. In many embodiments, the sacrificial layer portions are removed by etching adjacent the patterned mask material, for example, with a selective, anisotropic etch that removes first and second portions of the sacrificial layer (e.g., not covered by the patterned mask material) and retains the dielectric walls. The first and second portions of the sacrificial layer are those portions adjacent corresponding sidewalls of the uncovered portions of the dielectric wall: the first portion of the sacrificial layer is between the dielectric wall and the first stack of material layers, and the second portion of the sacrificial layer is between the dielectric wall and the second stack of material layers.

Removing the uncovered portions of the sacrificial layer may expose the (second) portions of the dielectric wall and of the first and second stacks of material layers not covered by the patterned mask material, for example, as exposed structures retained extending between and under parallel lines of dummy-gate material.

FIG. 3D illustrates dummy-gate material 326 over dielectric walls 140 and stacks 121 of layers 320, 330, and hardmask material 349 over dummy-gate material 326, in workpiece or device 100, in accordance with some embodiments, for example, following a performance of removing, patterning, and removing operations 240, 250, and 260. Dashed lines indicate borders not in the viewing plane, e.g., behind and seen through the viewing plane. For example, viewing plane A-A′ is through dielectric walls 140 and stacks 121 where the source-drain trench may become, and dummy-gate and hardmask materials 326, 349 are dashed, behind viewing plane A-A′. The retained portions of sacrificial layer 332 in FIG. 3D are dashed, behind viewing plane A-A′, retained under dummy-gate and hardmask materials 326, 349. Dielectric walls 140 and stacks 121 are exposed between dummy-gate materials 326 (e.g., between dummy-gate materials 326 in FIG. 3D and dummy-gate materials 326, not shown, behind viewing plane A-A′).

Returning to FIG. 2, methods 200 continue by depositing a spacer layer at operation 270. The spacer layer may be deposited (e.g., conformally) over the entire substrate, over the patterned mask material and the (masked) first portions of the dielectric wall and of the first and second stacks of material layers, as well as the (not masked) second portions of the dielectric wall and of the first and second stacks of material layers. Depositing the spacer layer may form sidewalls on (for example, dummy-gate) material covered by the patterned mask material. The spacer layer sidewalls may divide the gate and source-drain regions of the to-be-formed transistor structures.

The spacer layer may be deposited by any suitable means and of any suitable material(s). The spacer layer may be deposited by a conformal deposition method, such as an ALD or a CVD (chemical vapor deposition). The spacer layer advantageously provides etch selectivities with materials covered by the spacer layer. In some embodiments, the spacer layer has a composition similar to the dielectric walls. In many embodiments, the spacer layer includes silicon and nitrogen (e.g., in a nitride of silicon). In some embodiments, the spacer layer includes silicon and oxygen (e.g., in an oxide of silicon). In some embodiments, the spacer layer includes carbon and/or nitrogen, for example, in addition to silicon and oxygen.

Another mask material may be deposited over the gate regions (e.g., covered by the patterned mask material). In some embodiments, a mask (e.g., hardmask) material is deposited over the spacer layer over the patterned mask material. In some such embodiments, the deposited hardmask material includes titanium and nitrogen (e.g., in a titanium nitride). The deposited mask material may be deposited by a sputter or other PVD (physical vapor deposition) to be significantly thicker (and provide more of an etch selectivity) at tops of the gate regions (e.g., dummy-gate material covered by the patterned mask material).

FIG. 3E shows spacer material 347 over dielectric walls 140 and stacks 121 of layers 320, 330 in workpiece or device 100, in accordance with some embodiments, for example, following a performance of depositing operation 270. Spacer material 347 and dielectric walls 140 may have similar compositions, and, in some embodiments, deposited spacer material 347 may be on and continuous with dielectric walls 140. With dashed borders, a sidewall of spacer material 347 and hardmask material 337 over the sidewall of spacer material 347 (e.g., at a top of the sidewall of spacer material 347) are behind viewing plane A-A′. The sidewall of spacer material 347 is a spacer 147 (e.g., much as described at least at FIGS. 1B-1D), which is between the gate and source-drain regions. The spacer material 347 over dielectric walls 140 may be continuous with the sidewall of spacer material 347, e.g., after a conformal deposition of spacer material 347.

Returning to FIG. 2, methods 200 continue with etching adjacent the patterned mask material at operation 280. The etching adjacent the patterned mask material may remove the (not masked) second portions of the first and second stacks of material layers, while retaining the (masked) first portions of the dielectric wall and of the first and second stacks of material layers. Though not masked, at least some of the second portions of the dielectric wall may be retained, for example, as shortened walls, eroded by the etch, which may be somewhat selective to the material of the dielectric walls. By removing the second (not masked) portions of the first and second stacks of material layers, the etching adjacent the patterned mask material may expose ends of the first (masked) portions of the first and second stacks of material layers (e.g., with the first portion of the dielectric wall between the exposed ends of the masked portions of the material layer stacks).

FIG. 3F illustrates exposed ends of layers 320, 330 in stacks 121A, 121B extending through spacer 147 in workpiece or device 100, in accordance with some embodiments, for example, following a performance of etching operation 280. Dashed borders indicate that layers 320, 330 in stacks 121A, 121B are behind viewing plane A-A′, e.g., after portions of layers 320, 330 were removed by an etch adjacent materials 347, 337. Portions (e.g., dashed subfins) of substrate 199 are recessed and behind viewing plane A-A′. Dielectric walls 140 are reduced in height (e.g., eroded), particularly in the viewing plane A-A′, and dashed portions of walls 140 and spacer material 347 have a somewhat taller height behind viewing plane A-A′, at spacer 147. Dielectric walls (not shown) are undisturbed under and on the other side of spacer 147, for example, in a gate region. Spacer material 347 and reduced walls 140 may collectively form isolation structures between stacks 121 (e.g., must as described of isolation structures 174 at FIG. 1D).

Returning to FIG. 2, methods 200 continue at operation 290 by forming first and second gate structures. First and second gate structures may be formed over the first and second stacks of material layers, respectively, e.g., on opposing sidewalls of the dielectric wall between the first and second gate structures. In many embodiments, forming the first gate structure includes depositing a first gate insulator layer over the first stack of material layers and on a first sidewall of the dielectric wall (to the side of the first stack of material layers), and forming the second gate structure includes depositing a second gate insulator layer over the second stack of material layers and on a second sidewall of the dielectric wall (to the side of the second stack of material layers).

The first and second gate structures may be formed by any suitable means and of any suitable materials. In many embodiments, forming the first and second gate structures includes forming source and drain epi bodies in the source-drain region before releasing channel material layers in the gate region. In many embodiments, forming source and drain epi bodies includes, in the source-drain region, (first) recessing sacrificial layers between (or at least adjacent) the channel material layers, (second) depositing spacer material in the recesses between or otherwise adjacent the channel material layers, and epitaxially growing the source and drain bodies from the exposed ends of the channel material layers. In many embodiments, the source-drain region is filled by a low-k dielectric deposited in and on an etch-stop liner layer conformally deposited over the source and drain bodies and the source-drain region. In many embodiments, releasing the channel material layers in the gate region includes (first) removing (non-spacer) mask materials over the channel material layers in the gate region (between the sidewall spacers), (second) removing dummy-gate materials over the material layer stacks in the gate region (between the sidewall spacers), and (third) removing sacrificial material layers between (or otherwise on and above or below) the channel material layers in the gate region (between the sidewall spacers), which may make available the released channel material layers. The released and available channel material layers may be considered nanoribbons, extending through sidewalls spacers and coupled with source and drain epi bodies at both nanoribbon ends.

The first and second gate structures may be formed by conformally depositing the first and second gate insulator layers over the first and second stacks of released channel material layers (e.g., nanoribbon stacks), respectively, and on the corresponding opposing first and second sidewalls of the dielectric wall. The first and second gate insulator layers may be much as described of layers 123A, 123B at FIG. 1A, etc.

The first and second gate structures may be formed by depositing electrodes (e.g., of one or more gate metals) on the gate insulator layers. The depositing of gate metals may include conformally depositing one or more WFM layers on the first and/or second gate insulator layers, around the released nanoribbons and on the first and second sidewalls of the dielectric wall. WFM layers may be much as described of layers 127 at FIG. 1A, etc. The depositing of gate metals may include depositing one or more fill metal layers around, between, etc., the nanoribbons, e.g., on the WFM layers.

FIG. 3G shows exposed ends of nanoribbons 120 in stacks 121A, 121B extending through spacer 147 and to the source-drain region (but behind viewing plane A-A′) in workpiece or device 100, in accordance with some embodiments, for example, during a performance of forming operation 290. Spacer material 347 is deposited between exposed ends of nanoribbons 120 and adjacent trench isolations 334. In some embodiments, dimple spacers (between nanoribbons 120 in a given stack 121) are a different spacer material than spacer 147.

FIG. 3H illustrates source or drain bodies 110A, 110B spanning between eroded dielectric walls 140 and spacer material 347 in workpiece or device 100, in accordance with some embodiments, for example, during a performance of forming operation 290. Bodies 110 are grown to the confines of spacer material 347. Nanoribbons (not shown) are behind source or drain bodies 110A, 110B, which are coupled with ends of the nanoribbons. Spacer 147 is behind bodies 110A, 110B (and viewing plane A-A′).

FIG. 3I shows dielectric layer 143 on source or drain bodies 110A, 110B, and dielectric material 144 on layer 143 in workpiece or device 100, in accordance with some embodiments, for example, during a performance of forming operation 290. Dielectric layer 143 may be an etch-stop layer 143 on bodies 110 and may protect bodies 110 from dielectric material 144, which may be an oxidation-inducing material 144.

FIG. 3J illustrates nanoribbons 120 in gate tubs 325 between dielectric walls 140 in workpiece or device 100, in accordance with some embodiments, for example, during a performance of forming operation 290. Viewing plane B-B′ is through a gate region (e.g., between spacers 147), and gate tubs 325 are in the gate region, between dielectric walls 140 and between spacers 147. Dielectric walls 140 and nanoribbons 120 are in viewing plane A-A′. Spacer 147 is behind viewing plane A-A′.

FIG. 3K shows gate insulator layers 123 on nanoribbons 120 and sidewalls 141, 142 of dielectric walls 140 in gate tubs 325 in workpiece or device 100, in accordance with some embodiments, for example, during a performance of forming operation 290. Viewing plane B-B′ is through gate tubs 325, nanoribbons 120, and dielectric walls 140 and between spacers 147. Dielectric walls 140 and nanoribbons 120 are in viewing plane A-A′, as are layers 123 conformally on nanoribbons 120 and walls 140. Gate insulator layers 123 are behind viewing plane A-A′ on spacer sidewalls.

FIG. 3L illustrates transistor structures 101A, 101B having gate stacks 125 between dielectric walls 140 and over nanoribbons 120 in IC device 100, in accordance with some embodiments, for example, following a performance of forming operation 290. Gate stacks 125 include insulator layers 123 and electrodes 126. Gate insulator layers 123 are between electrodes 126 and nanoribbons 120 and between electrodes 126 and dielectric walls 140. Layers 123 are on nanoribbons 120 and on sidewalls 141, 142 of dielectric walls 140.

IC device 100 may include or be coupled to a substrate or other host component 399. Host component 399 may be a package substrate, an interposer, an IC die, etc. For example, substrate 199 may be an IC die that includes transistor structures 101, substrate 199 may be coupled (e.g., soldered or otherwise bonded) with host component 399, and transistor structures 101 may be coupled with a power supply (not shown) through host component 399.

Host component 399 is a planar platform and may include dielectric and metallization structures. Host component 399 mechanically supports and electrically couples one or more IC devices 100. At least one side of host component 399 includes substrate interconnect interfaces for bonding to one or more IC devices 100. IC device 100 may be direct bonded, e.g., hybrid bonded, to host component 399 or otherwise bonded, e.g., by optional solder bumps. The opposite side of host component 399 may include similar interfaces, e.g., copper pads for socketing and/or solder bumps for bonding device 100 to a host component, such as a printed circuit board (PCB). Host component 399 may be any host component with substrate interconnect interfaces, such as a package host component 399 or interposer, etc. Host component 399 may itself be a die. In many embodiments, host component 399 includes organic dielectric(s), such as a resin or other polymer, between metallization layers.

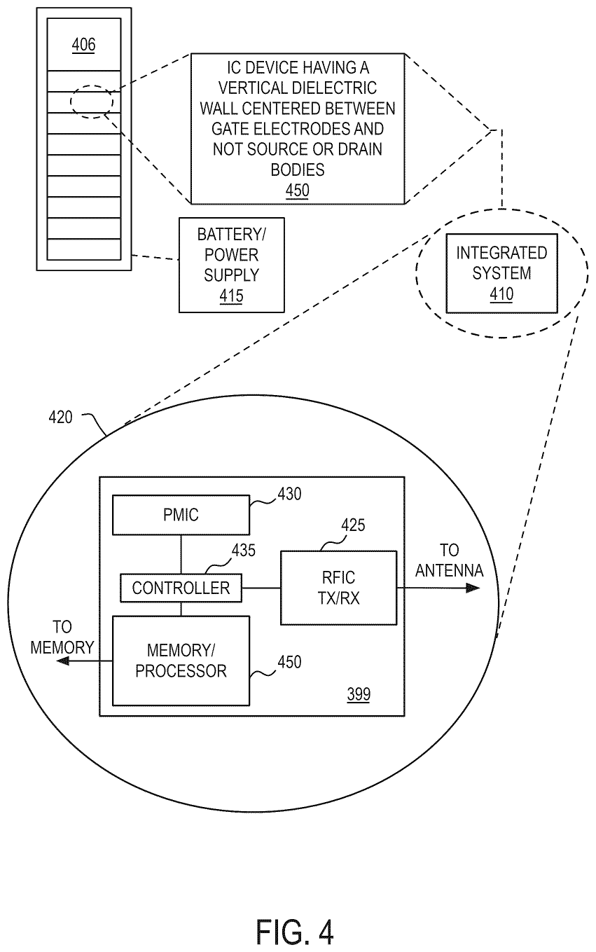

FIG. 4 illustrates a diagram of an example data server machine 406 employing an IC device having vertical dielectric walls that extend between gate electrodes but not to between source and drain bodies, in accordance with some embodiments. Server machine 406 may be any commercial server, for example, including any number of high-performance computing platforms disposed within a rack and networked together for electronic data processing, which in the exemplary embodiment includes one or more devices 450 having vertical dielectric walls that are between gate electrodes and not between source and drain bodies.

Also as shown, server machine 406 includes a battery and/or power supply 415 to provide power to devices 450, and to provide, in some embodiments, power delivery functions such as power regulation. Devices 450 may be deployed as part of a package-level integrated system 410. Integrated system 410 is further illustrated in the expanded view 420. In the exemplary embodiment, devices 450 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 450 is a microprocessor including a static RAM (SRAM) cache memory. As shown, device 450 may be an IC device having vertical dielectric walls that are between gate electrodes and not between source and drain bodies, as discussed herein. Device 450 may be further coupled to (e.g., communicatively coupled to) a board, an interposer, or other substrate or host component 399 along with, one or more of a power management IC (PMIC) 430, RF (wireless) IC (RFIC) 425 including a wideband RF (wireless) transmitter and/or receiver (TX/RX) (e.g., including a digital baseband and an analog front-end module further includes a power amplifier on a transmit path and a low noise amplifier on a receive path), and a controller 435 thereof. In some embodiments, RFIC 425, PMIC 430, controller 435, and device 450 include having vertical dielectric walls that are between gate electrodes and not between source and drain bodies.

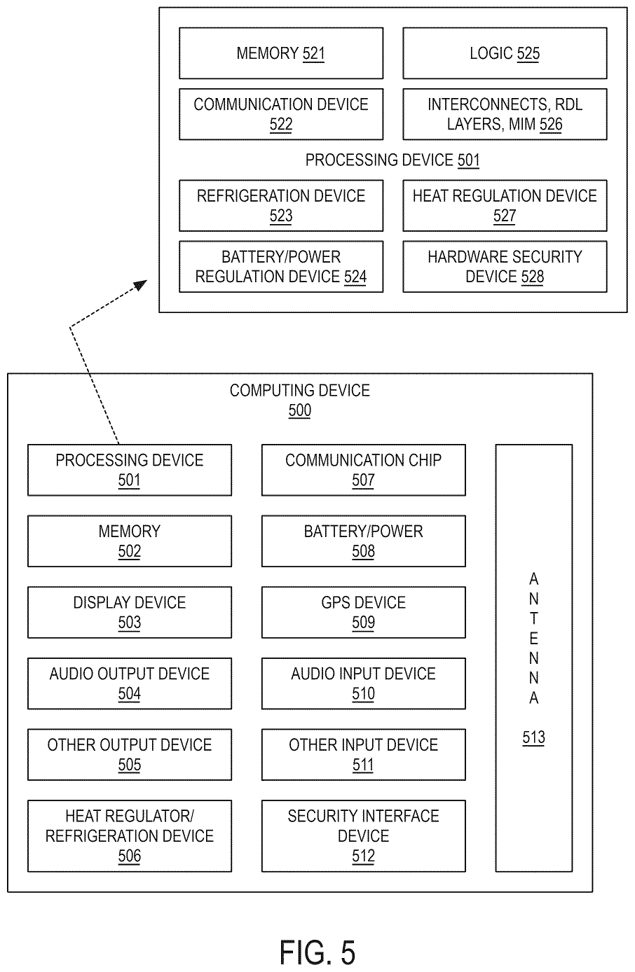

FIG. 5 is a block diagram of an example computing device 500, in accordance with some embodiments. For example, one or more components of computing device 500 may include any of the devices or structures discussed herein. A number of components are illustrated in FIG. 5 as being included in computing device 500, but any one or more of these components may be omitted or duplicated, as suitable for the application. In some embodiments, some or all of the components included in computing device 500 may be attached to one or more printed circuit boards (e.g., a motherboard). In some embodiments, various ones of these components may be fabricated onto a single system-on-a-chip (SoC) die. Additionally, in various embodiments, computing device 500 may not include one or more of the components illustrated in FIG. 5, but computing device 500 may include interface circuitry for coupling to the one or more components. For example, computing device 500 may not include a display device 503, but may include display device interface circuitry (e.g., a connector and driver circuitry) to which display device 503 may be coupled. In another set of examples, computing device 500 may not include an audio output device 504, other output device 505, global positioning system (GPS) device 509, audio input device 510, or other input device 511, but may include audio output device interface circuitry, other output device interface circuitry, GPS device interface circuitry, audio input device interface circuitry, audio input device interface circuitry, to which audio output device 504, other output device 505, GPS device 509, audio input device 510, or other input device 511 may be coupled.

Computing device 500 may include a processing device 501 (e.g., one or more processing devices). As used herein, the term “processing device” or “processor” indicates a device that processes electronic data from registers and/or memory to transform that electronic data into other electronic data that may be stored in registers and/or memory. Processing device 501 may include a memory 521, a communication device 522, a refrigeration device 523, a battery/power regulation device 524, logic 525, interconnects 526 (i.e., optionally including redistribution layers (RDL) or metal-insulator-metal (MIM) devices), a heat regulation device 527, and a hardware security device 528.

Processing device 501 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 500 may include a memory 502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 502 includes memory that shares a die with processing device 501. This memory may be used as cache memory and may include embedded dynamic random-access memory (eDRAM) or spin transfer torque magnetic random-access memory (STT-MRAM).

Computing device 500 may include a heat regulation/refrigeration device 506. Heat regulation/refrigeration device 506 may maintain processing device 501 (and/or other components of computing device 500) at a predetermined low temperature during operation.

In some embodiments, computing device 500 may include a communication chip 507 (e.g., one or more communication chips). For example, the communication chip 507 may be configured for managing wireless communications for the transfer of data to and from computing device 500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 507 may operate in accordance with other wireless protocols in other embodiments. Computing device 500 may include an antenna 513 to facilitate wireless communications and/or to receive other wireless communications (such as AM or FM radio transmissions).

In some embodiments, communication chip 507 may manage wired communications, such as electrical, optical, or any other suitable communication protocols (e.g., the Ethernet). As noted above, communication chip 507 may include multiple communication chips. For instance, a first communication chip 507 may be dedicated to shorter-range wireless communications such as Wi-Fi or Bluetooth, and a second communication chip 507 may be dedicated to longer-range wireless communications such as GPS, EDGE, GPRS, CDMA, WiMAX, LTE, EV-DO, or others. In some embodiments, a first communication chip 507 may be dedicated to wireless communications, and a second communication chip 507 may be dedicated to wired communications.

Computing device 500 may include battery/power circuitry 508. Battery/power circuitry 508 may include one or more energy storage devices (e.g., batteries or capacitors) and/or circuitry for coupling components of computing device 500 to an energy source separate from computing device 500 (e.g., AC line power).

Computing device 500 may include a display device 503 (or corresponding interface circuitry, as discussed above). Display device 503 may include any visual indicators, such as a heads-up display, a computer monitor, a projector, a touchscreen display, a liquid crystal display (LCD), a light-emitting diode display, or a flat panel display, for example.

Computing device 500 may include an audio output device 504 (or corresponding interface circuitry, as discussed above). Audio output device 504 may include any device that generates an audible indicator, such as speakers, headsets, or earbuds, for example.

Computing device 500 may include an audio input device 510 (or corresponding interface circuitry, as discussed above). Audio input device 510 may include any device that generates a signal representative of a sound, such as microphones, microphone arrays, or digital instruments (e.g., instruments having a musical instrument digital interface (MIDI) output).

Computing device 500 may include a GPS device 509 (or corresponding interface circuitry, as discussed above). GPS device 509 may be in communication with a satellite-based system and may receive a location of computing device 500, as known in the art.

Computing device 500 may include other output device 505 (or corresponding interface circuitry, as discussed above). Examples of the other output device 505 may include an audio codec, a video codec, a printer, a wired or wireless transmitter for providing information to other devices, or an additional storage device.

Computing device 500 may include other input device 511 (or corresponding interface circuitry, as discussed above). Examples of the other input device 511 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 500 may include a security interface device 512. Security interface device 512 may include any device that provides security measures for computing device 500 such as intrusion detection, biometric validation, security encode or decode, access list management, malware detection, or spyware detection.

Computing device 500, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-5. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a stack of first nanoribbons extending through a first gate structure in a first transistor structure, the first gate structure including a first dielectric layer around an individual one of the first nanoribbons, a stack of second nanoribbons extending through a second gate structure in a second transistor structure, the second gate structure including a second dielectric layer around an individual one of the second nanoribbons, and a dielectric wall between the stacks of first and second nanoribbons, the dielectric wall including opposing first and second sidewalls, wherein the first and second sidewalls are substantially vertical, the first dielectric layer is on the first sidewall, and the second dielectric layer is on the second sidewall.

In one or more second embodiments, further to the first embodiments, a first width of the dielectric wall above the stack of first nanoribbons is approximately equal to a second width of the dielectric wall below the stack of second nanoribbons.

In one or more third embodiments, further to the first or second embodiments, a distance separating the stacks of first and second nanoribbons is at least three times greater than a width of the dielectric wall.

In one or more fourth embodiments, further to the first through third embodiments, a distance separating the stacks of first and second nanoribbons is less than half of a height of the stack of first nanoribbons.

In one or more fifth embodiments, further to the first through fourth embodiments, the dielectric wall is a first dielectric wall extending laterally in a first direction, the apparatus also includes second and third dielectric walls extending laterally in a second direction, orthogonal to the first direction, the first dielectric wall between the second and third dielectric walls, a first end of the first dielectric wall on the second dielectric wall, a second end of the first dielectric wall on the third dielectric wall.

In one or more sixth embodiments, further to the first through fifth embodiments, the apparatus also includes fourth, fifth, sixth, and seventh dielectric walls and first, second, third, and fourth source or drain bodies, wherein the first nanoribbons extend through the first gate structure between the first and third source or drain bodies, the second nanoribbons extend through the second gate structure between the second and fourth source or drain bodies, the fourth and fifth dielectric walls extend laterally in the first direction, the fourth dielectric wall extends between the first and second source or drain bodies, the fifth dielectric wall extends between the third and fourth source or drain bodies, the sixth and seventh dielectric walls extend laterally in the second direction, the second and third dielectric walls are between the sixth and seventh dielectric walls, the first and second source or drain bodies are between the second and sixth dielectric walls, and the third and fourth source or drain bodies are between the third and seventh dielectric walls.

In one or more seventh embodiments, further to the first through sixth embodiments, the first nanoribbons are coupled with a first source or drain body, the second dielectric wall between the first gate structure and the first source or drain body, the second nanoribbons are coupled with a second source or drain body, the second dielectric wall between the second gate structure and the second source or drain body, a first dielectric material is between the first and second source or drain bodies, and a layer of a second dielectric material is on the first and second source or drain bodies, on the second dielectric wall, between the first dielectric material and the second dielectric wall, between the first dielectric material and the first source or drain body, and between the first dielectric material and the second source or drain body.

In one or more eighth embodiments, further to the first through seventh embodiments, the first gate structure includes a first metal, the second gate structure includes a second metal, and a first thickness of the first metal between the stack of first nanoribbons and the dielectric wall is approximately equal to a second thickness of the second metal between the stack of second nanoribbons and the dielectric wall.

In one or more ninth embodiments, further to the first through eighth embodiments, the first and second thicknesses are greater than a width of the dielectric wall.

In one or more tenth embodiments, further to the first through ninth embodiments, the first and second transistor structures are in a first substrate, the first substrate is coupled with a second substrate, and the first and second transistor structures are coupled with a power supply by the second substrate.

In one or more eleventh embodiments, an apparatus includes a stack of first nanoribbons extending through a first gate structure in a first transistor structure, the first gate structure including a first dielectric layer, a stack of second nanoribbons extending through a second gate structure in a second transistor structure, the second gate structure including a second dielectric layer, and a first dielectric wall between the stacks of first and second nanoribbons and between second and third dielectric walls, the first dielectric wall including first and second ends and opposing first and second sidewalls, wherein the first dielectric layer is on the first sidewall, the second dielectric layer is on the second sidewall, and the first dielectric wall and the first and second gate structures are between the second and third dielectric walls, the first end on the second dielectric wall, the second end on the third dielectric wall.

In one or more twelfth embodiments, further to the eleventh embodiments, the first and second sidewalls of the first dielectric wall are substantially vertical.

In one or more thirteenth embodiments, further to the eleventh or twelfth embodiments, each of the first and second sidewalls of the first dielectric wall are less than half of one degree from vertical.

In one or more fourteenth embodiments, further to the eleventh through thirteenth embodiments, a width of the first dielectric wall between the first and second sidewalls is less than 10 nm.

In one or more fifteenth embodiments, further to the eleventh through fourteenth embodiments, the first and second transistor structures are in a first substrate, the first substrate is coupled with a second substrate, and the first and second transistor structures are coupled with a power supply by the second substrate.

In one or more sixteenth embodiments, a method includes forming first and second sidewalls between first and second stacks of material layers by depositing a sacrificial layer over and between the first and second stacks, forming a dielectric wall including third and fourth sidewalls on and between the first and second sidewalls by depositing a dielectric layer over and between the first and second sidewalls and over and between the first and second stacks, wherein a first distance between the dielectric wall and the first stack is approximately equal to a second distance between the dielectric wall and the second stack, and removing first and second portions of the sacrificial layer, the first portion of the sacrificial layer between the dielectric wall and the first stack of material layers, the second portion of the sacrificial layer between the dielectric wall and the second stack of material layers.

In one or more seventeenth embodiments, further to the sixteenth embodiments, the method also includes removing a lateral portion of the sacrificial layer by etching between the first and second sidewalls.

In one or more eighteenth embodiments, further to the sixteenth or seventeenth embodiments, the method also includes removing upper portions of the sacrificial and dielectric layers over the first and second stacks of material layers, patterning a mask material over first portions of the dielectric wall and of the first and second stacks of material layers, wherein the patterned mask material does not cover second portions of the dielectric wall and of the first and second stacks of material layers, and the first and second portions of the sacrificial layer, and etching adjacent the patterned mask material, wherein the etching removes the first and second portions of the sacrificial layer.

In one or more nineteenth embodiments, further to the sixteenth through eighteenth embodiments, the method also includes depositing a spacer layer over the patterned mask material and the first portions of the dielectric wall and of the first and second stacks of material layers, and the second portions of the dielectric wall and of the first and second stacks of material layers, and etching adjacent the patterned mask material, wherein the etching removes the second portions of the first and second stacks of material layers, and exposes ends of the first portions of the first and second stacks of material layers, the first portion of the dielectric wall between the exposed ends of the first portions of the first and second stacks of material layers.

In one or more twentieth embodiments, further to the sixteenth through nineteenth embodiments, the method also includes forming first and second gate structures, the first gate structure over the first stack of material layers, the second gate structure over the second stack of material layers, wherein forming the first gate structure includes depositing a first insulator layer on the third sidewall of the dielectric wall and over the first stack of material layers, and forming the second gate structure includes depositing a second insulator layer on the fourth sidewall of the dielectric wall and over the second stack of material layers.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a stack of first nanoribbons extending through a first gate structure in a first transistor structure, the first gate structure comprising a first dielectric layer around an individual one of the first nanoribbons;
a stack of second nanoribbons extending through a second gate structure in a second transistor structure, the second gate structure comprising a second dielectric layer around an individual one of the second nanoribbons; and
a dielectric wall between the stacks of first and second nanoribbons, the dielectric wall comprising opposing first and second sidewalls, wherein the first and second sidewalls are substantially vertical, the first dielectric layer is on the first sidewall, and the second dielectric layer is on the second sidewall.

2. The apparatus of claim 1, wherein a first width of the dielectric wall above the stack of first nanoribbons is approximately equal to a second width of the dielectric wall below the stack of second nanoribbons.

3. The apparatus of claim 1, wherein a distance separating the stacks of first and second nanoribbons is at least three times greater than a width of the dielectric wall.

4. The apparatus of claim 1, wherein a distance separating the stacks of first and second nanoribbons is less than half of a height of the stack of first nanoribbons.

5. The apparatus of claim 1, wherein the dielectric wall is a first dielectric wall extending laterally in a first direction, further comprising second and third dielectric walls extending laterally in a second direction, orthogonal to the first direction, the first dielectric wall between the second and third dielectric walls, a first end of the first dielectric wall on the second dielectric wall, a second end of the first dielectric wall on the third dielectric wall.

6. The apparatus of claim 5, further comprising fourth, fifth, sixth, and seventh dielectric walls and first, second, third, and fourth source or drain bodies, wherein:
the first nanoribbons extend through the first gate structure between the first and third source or drain bodies;
the second nanoribbons extend through the second gate structure between the second and fourth source or drain bodies;
the fourth and fifth dielectric walls extend laterally in the first direction;
the fourth dielectric wall extends between the first and second source or drain bodies;
the fifth dielectric wall extends between the third and fourth source or drain bodies;
the sixth and seventh dielectric walls extend laterally in the second direction;
the second and third dielectric walls are between the sixth and seventh dielectric walls;
the first and second source or drain bodies are between the second and sixth dielectric walls; and
the third and fourth source or drain bodies are between the third and seventh dielectric walls.

7. The apparatus of claim 5, wherein:
the first nanoribbons are coupled with a first source or drain body, the second dielectric wall between the first gate structure and the first source or drain body;
the second nanoribbons are coupled with a second source or drain body, the second dielectric wall between the second gate structure and the second source or drain body;
a first dielectric material is between the first and second source or drain bodies; and
a layer of a second dielectric material is:
on the first and second source or drain bodies;
on the second dielectric wall;
between the first dielectric material and the second dielectric wall;
between the first dielectric material and the first source or drain body; and
between the first dielectric material and the second source or drain body.

8. The apparatus of claim 1, wherein:
the first gate structure comprises a first metal;
the second gate structure comprises a second metal; and
a first thickness of the first metal between the stack of first nanoribbons and the dielectric wall is approximately equal to a second thickness of the second metal between the stack of second nanoribbons and the dielectric wall.

9. The apparatus of claim 8, wherein the first and second thicknesses are greater than a width of the dielectric wall.

10. The apparatus of claim 1, wherein:
the first and second transistor structures are in a first substrate;
the first substrate is coupled with a second substrate; and
the first and second transistor structures are coupled with a power supply by the second substrate.

11. An apparatus, comprising:
a stack of first nanoribbons extending through a first gate structure in a first transistor structure, the first gate structure comprising a first dielectric layer;
a stack of second nanoribbons extending through a second gate structure in a second transistor structure, the second gate structure comprising a second dielectric layer; and
a first dielectric wall between the stacks of first and second nanoribbons and between second and third dielectric walls, the first dielectric wall comprising first and second ends and opposing first and second sidewalls, wherein the first dielectric layer is on the first sidewall, the second dielectric layer is on the second sidewall, and the first dielectric wall and the first and second gate structures are between the second and third dielectric walls, the first end on the second dielectric wall, the second end on the third dielectric wall.

12. The apparatus of claim 11, wherein the first and second sidewalls of the first dielectric wall are substantially vertical.

13. The apparatus of claim 12, wherein each of the first and second sidewalls of the first dielectric wall are less than half of one degree from vertical.

14. The apparatus of claim 13, wherein a width of the first dielectric wall between the first and second sidewalls is less than 10 nm.

15. The apparatus of claim 11, wherein:
the first and second transistor structures are in a first substrate;
the first substrate is coupled with a second substrate; and
the first and second transistor structures are coupled with a power supply by the second substrate.

16. A method, comprising:
forming first and second sidewalls between first and second stacks of material layers by depositing a sacrificial layer over and between the first and second stacks;
forming a dielectric wall comprising third and fourth sidewalls on and between the first and second sidewalls by depositing a dielectric layer over and between the first and second sidewalls and over and between the first and second stacks, wherein a first distance between the dielectric wall and the first stack is approximately equal to a second distance between the dielectric wall and the second stack; and
removing first and second portions of the sacrificial layer, the first portion of the sacrificial layer between the dielectric wall and the first stack of material layers, the second portion of the sacrificial layer between the dielectric wall and the second stack of material layers.

17. The method of claim 16, further comprising removing a lateral portion of the sacrificial layer by etching between the first and second sidewalls.

18. The method of claim 16, further comprising:
removing upper portions of the sacrificial and dielectric layers over the first and second stacks of material layers;
patterning a mask material over first portions of the dielectric wall and of the first and second stacks of material layers, wherein the patterned mask material does not cover:
second portions of the dielectric wall and of the first and second stacks of material layers; and
the first and second portions of the sacrificial layer; and
etching adjacent the patterned mask material, wherein the etching removes the first and second portions of the sacrificial layer.

19. The method of claim 18, further comprising:
depositing a spacer layer over:
the patterned mask material and the first portions of the dielectric wall and of the first and second stacks of material layers; and
the second portions of the dielectric wall and of the first and second stacks of material layers; and
etching adjacent the patterned mask material, wherein the etching:
removes the second portions of the first and second stacks of material layers; and
exposes ends of the first portions of the first and second stacks of material layers, the first portion of the dielectric wall between the exposed ends of the first portions of the first and second stacks of material layers.

20. The method of claim 16, further comprising forming first and second gate structures, the first gate structure over the first stack of material layers, the second gate structure over the second stack of material layers, wherein forming the first gate structure comprises depositing a first insulator layer on the third sidewall of the dielectric wall and over the first stack of material layers, and forming the second gate structure comprises depositing a second insulator layer on the fourth sidewall of the dielectric wall and over the second stack of material layers.
